(19) United States
(12) Patent Application Publication
(10) Pub. No.: US 2004/0026684 A1
(43) Pub. Date: Feb. 12, 2004

(54) Nanowire heterostructures for encoding information

(75) Inventor: Stephen Empedocles, Mountain View, CA (US)

Correspondence Address: QUINE INTELLECTUAL PROPERTY LAW GROUP, P.C., P O BOX 458, ALAMEDA, CA, 94501, US

(73) Assignee: Nanosys, Inc.

(21) Appl. No.: 10/405,914

(22) Filed: Apr. 1, 2003

Related U.S. Application Data
(60) Provisional application No. 60/370,095, filed on Apr. 2, 2002.

(51) Int. Cl. H01L 29/06

(52) U.S. Cl. 257/14

(57) ABSTRACT

This invention pertains to the synthesis and use of nanowire heterostructures for the storage of information. In certain embodiments, the nanowire heterostructures comprise at least a first material type and a second material type wherein the first material type and the second material type delineate at least two different and distinguishable domains, wherein said domains store coded information. The nanowire heterostructures are particularly useful for identifying, tagging, and tracking compositions, articles of manufacture, or animals. The nanowire heterostructure are also useful for various assays and for storing and recovering information.

### CROSS-REFERENCE TO RELATED APPLICATIONS

This application claims priority to and benefit of U.S. provisional application U.S. Ser. No. 60/370,095, filed on Apr. 2, 2002, which is incorporated herein by reference in its entirety for all purposes.

### STATEMENT AS TO RIGHTS TO INVENTIONS MADE UNDER FEDERALLY SPONSORED RESEARCH AND DEVELOPMENT

[Not Applicable ]

### FIELD OF THE INVENTION

This invention pertains to the field of nanotechnology. More particularly, this invention pertains to the synthesis and use of nanowire heterostructures for the storage of information.

### BACKGROUND OF THE INVENTION

Storage media, particularly non-volatile storage media, encoding information, finds use in a wide variety of applications particularly where the storage media is chemically robust, easily read, and provides information storage at high density. For example, information encoded into such non-volatile storage media can provide populations of tags (labels) that can be used to uniquely label or track compositions, materials, or objects of manufacture. Such materials can also be used to encrypt and/or to transport information.

Collections of tags comprising such storage media can be used as labels in a wide variety of chemical and biological assays, e.g., to identify an analyte of interest in a given sample. For example, immunoassays, such as enzyme-linked immunosorbent assays (ELISAs) are used in numerous diagnostic, research and screening applications. In its most common form, an ELISA detects the presence and/or concentration of an analyte in a sample using an antibody that specifically recognizes the analyte where the antibody is immediately or ultimately associated with a detectable label that indicates the presence and/or quantity of analyte in the sample.

Detectable labels or tags can also be used in nucleic acid hybridization assays including, but not limited to array-based hybridizations, in situ hybridization, and the like. Such assays typically utilize one or more tags associated with either the target nucleic acids, or with probes that specifically hybridize to the target nucleic acids to indicate the presence and/or quantity of target nucleic acid.

It is often desirable to perform such assays in a “highly parallel” (e.g. multiplexed) format. The throughput of such multiplexed assays, however, is also limited by the availability of multiple tags that can be readily detected and distinguished from each other thereby providing unique identification/quantification of each analyte in the assay.

Encoded information units (e.g. tags) can also be used to indicated track and/or indicate the origin of various molecules, compositions, and/or articles of manufacture. Such materials include, but are not limited to drugs, chemical toxins, biohazards, currency, explosives, weapons, and the like.

Finally, in some applications, discrete tags are used to secretly label, track and/or identify an object. Such tags can be used as security inks to authenticate items of value such as money, artwork, or legal documents, and also to label items of interest so that the item(s) can be identified at a later date if they are lost, stolen or moved. In the case of security inks, it is desirable that the tags be difficult to replicate or forge, and/or being difficult to detect unaided, for instance being invisible or nearly invisible to the human eye.

### SUMMARY OF THE INVENTION

This invention pertains to novel methods and compositions for encoding information. The methods utilize nanowire heterostructures (e.g. nanowires comprising at least two different and distinguishable materials (material types). The spatial disposition and/or material characteristics of regions comprising particular material types along the length of the nanowire can be used to encode information much the way the “universal bar code” encodes information in a particular distribution of stripes and intervening spaces along a “read” path (see, e.g., FIG. 1). Nanowires, however typically store such information in a much smaller spatial scale. In addition, nanowires can be formed from materials that emit a detectable code only in the infrared (IR) region of the electromagnetic (EM) spectrum, where it can not be detected by the human eye without the assistance of an IR detection device.

Thus, in one embodiment, this invention provides a nanowire heterostructure comprising at least a first material type and a second material type wherein the first material type and the second material type delineate at least two different and distinguishable domains, wherein the domains store coded information. In certain embodiments, the nanowire heterostructure has a substantially uniform diameter of about 200 nm or less. In certain embodiments, the nanowire has an aspect ration greater than about 2. The nanowire heterostructure can store an enormous amount of information. In certain embodiments, the nanowire heterostructure stores at least two bits, preferably at least 4, 8,, 16, 64, or 128 bits of information, more preferably at least 256, 512, or 1024 bits of information, and most preferably lat least 2048, 4096, 8192, or 16334 bits of information. In other embodiments, non-binary bit densities can be provided. In certain embodiments, the information can be spatially encoded by the position of the domains along the nanowire and/or by the length of the domains along the nanowire. The information can be encoded by the physical properties of the domains (e.g. electrical, magnetic, optical properties, doping, etc.). In certain embodiments, one or more domains of the nanowire heterostructure are fluorescent or electroluminescent. Where one or more domains are fluorescent, information can be encoded in the fluorescence intensity, and/or the emission wavelength, and/or the absorption wavelength of the domains and/or their length and/or position. In fact, the intensity and or wavelength can be tuned precisely to generate a virtually limitless number of codes. In certain embodiments, the first material type and the second material type differ from each other in a property selected from the group consisting of an optical property, an electrical property, a chemical property (e.g., doping), and a magnetic property. The optical property can comprise one or more properties including, but not limited to a color, an absorption spectrum, an emission spectrum, , a scattering spectrum, a scattering intensity. and an emission intensity. In certain embodiments, the first material type and/or the second material type is a semiconductor (e.g. an n-doped semiconductor, a p-doped semiconductor, an intrinsic semiconductor, a variably doped semiconductor, etc.). The first and second materials can be the same materials and simply differ in doping levels or the first and second materials can be different materials. In some embodiments, the first material is a p-doped semiconductor and the second material is an n-doped semiconductor. In some embodiments, the first material is an n-doped semiconductor, the second material is a p-doped semiconductor and the transition region between the first and second materials is a fluorescent region. The materials can, optionally, have a shell to enhance quantum efficiency or to protect the molecules

In some embodiments, the information is encoded in the spatial distribution of a plurality of transition regions between n-doped and p-doped semiconductors comprising the nanowire heterostructure. In certain embodiments, the first material type and the second material type differ in magnetic properties.

Some heterostructures comprise at least a first domain and a second domain wherein the first domain differs in absorption or emission spectra from the second domain. Either or both domains can be fluorescent domains and the fluorescence can depend on the material comprising the domain and/or the diameter of the domain, and/or the length of the domain. In some embodiments, the effects of quantum confinement, as will be understood by one of skill, can be used to precisely control the absorption or emission spectra from either or both domains. In some embodiments, either or both domains have an essentially monochromatic emission spectrum. In certain embodiments, the first domain and the second domain are sufficiently close to each other that they can not be spatially resolved by optical means. In this case, these domains form a coding region having a polychromatic emission spectrum. What is meant by “polychromatic” is that the emission spectrum comprises two or more emission peaks that may or may not be partially overlapped. The nanowire heterostructure(s) can comprise a plurality of different fluorescent domains located within a region whose length is less than the wavelength of the longest wavelength of light emitted from the domains and/or a plurality of different fluorescent domains located within a region whose length is less than the diffraction limit of the light emitted by the domain emitting the longest wavelength of light. Such nanowire heterostructures can comprise a plurality of coding regions. These coding regions may or may not be separated by a distance that is greater than the diffraction limit of the longest wavelength of light emitted from either of the coding regions. In the case where two or more coding regions cannot be spatially resolved, they are considered to comprise a new coding region with a polychromatic emission comprising the sum of the emission from each of the individual coding regions. In certain embodiments, the nanowire heterostructure is less than about 500 nm long. Certain heterostructures can comprise ferroelectric materials. Certain heterostructures can operate in multiple modalities (e.g. fluorescence encoding and magnetic encoding in one bar code).

The nanowire heterostructure can be functionalized, e.g.,, with a functional group selected from the group consisting of a hydroxyl, an amino, a carboxyl, and a thiol and/or a binding moiety selected from the group consisting of a nucleic acid, an antibody, a polypeptide, a sugar, a lectin, a carbohydrate, a cell, a receptor, a small organic molecule, an avidin, a streptavidin, a biotin, an oligonucleotide, a polynucleotide, an aptamer, an aptazyme and a protein. In certain embodiments, the nanowire heterostructure is characterized by one or more of the following: a diameter of less than about 200 nm; . a substantially uniform diameter, a substantially crystalline core, and a substantially monocrystalline core.

In another embodiment this invention provides a collection of nanowire heterostructures, the collection comprising a plurality of nanowire heterostructures as described above (herein), wherein the nanowire heterostructures comprising the collection carry substantially the same code. Certain collections comprise at least about 10 members, preferably at least about 100 members, more preferably at least about 500 members, more preferably at least about 1000 members, more preferably at least about 10,000, and most preferably at least 25,000 different members. In certain embodiments, the variation in location, size and compositionof the domains comprising the nanowire heterostructures in the collection is sufficiently small so that it is possible to distinguish members of the collection from members of a second collection of nanowire heterostructures with a different set of characteristics. It is understood that no two items are infinitely distinguishable under all conditions, and that errors in identification can occur within these embodiment. In particular, a preferred embodiment comprises a collection of nanowire heterostructures that can be accurately identified and distinguished from a second collection of nanowires at least 50% of the time, under a certain set of conditions, more prefereably at least 75% of the time, more preferably at least 90% of the time, more preferably at least 99% of the time, more preferably at least 99.9% of the time. The members of the collection can be functionalized, e.g. as described herein, and the encoded information can, optionally, encode the identity of the functionality. The members of the collection can be electrically coupled to one or more electrodes, optically coupled to one or more photonic devices, form one or more junctions (e.g. ohmic junctions, non-ohmic junctions, tunneling junctions, etc.) with one or more second nanowires, and the like. Preferred junctions include of pn, pnp, npn, pi, pnp, npn, pi, pin, pip, and nin. In certain embodiments, the doping level of either side of the junction is substantially different. In many embodiments, the invention provides a collection of nanowires with an average diameter less than 200 nm, and a substantially monodisperse distribution of diameters. A monodisperse distribution of diameters typically refers to a collection of nanowires with a coefficient of variance less than about 100%, more preferably less than about 50%, more preferably less than 25%, most preferably less than 10%.

In still another embodiment, this invention provides a collection of nanowire heterostructures, the collection comprising two or more species of nanowire heterostructures as described herein, where each species is coded with information providing a signature unique for each species of nanowire heterostructure comprising the collection. Certain collections comprise at least about 10, 20, 50, 100, or 500 different members, preferably at least about 1,000 different members, more preferably at least about 10,000 different members, and most preferably at least 25,000 different members. The members of the collection can be functionalized, e.g. as described herein, and the encoded information can, optionally, encode the identity of the functionality, e.g., such that each species of coded nanowire is associated with a particular functionality. The members of the collection can be electrically coupled to one or more electrodes, optically coupled to one or more photonic devices, form one or more junctions (e.g. ohmic junctions, non-ohmic junctions, tunneling junctions, etc.) with one or more second nanowires, ,and the like. Preferred junctions include of pn, pnp, npn, pi, pnp, npn, pi, pin, pip, and nin. In certain embodiments, the doping level of either side of the junction is substantially different. In certain embodiments, the members of a particular species in such a collection have a substantially monodisperse distribution of diameters, with an average diameter less than about 200 nm. In certain embodiments, different species within the collection can have either substantially the same average diameter and diameter distribution or different average diameters and diameter distributions.

This invention also provides a junction comprising a nanowire heterostructure as described herein electrically or optically coupled to a second nanowire or to an electrode. The said junction can comprise a nanowire heterostructure electrically coupled to an electrode, wherein the electrical coupling is ohmic or non-ohmic. The said junction can comprise a nanowire heterostructure electrically coupled to a second nanowire, wherein the electrical coupling is ohmic or non-ohmic. In some embodiments, the electrical coupling can be via electron tunneling. Certain preferred junctions include pn, pnp, npn, pi, pnp, npn, pi, pin, pip, and nin. In one preferred junction, the doping level of either side of said junction is substantially different. The junction can be encapsulated and/or connected to a pinout, and/or an element of a circuit.

In still yet another embodiment, this invention provides a kit comprising a container containing a component selected from the group consisting of a nanowire heterostructure of as described herein, a homogeneous collection of nanowire heterostructures as described herein, a heterogeneous collection of nanowire heterostructures as described herein, a junction, and any of the previous members of the group further functionlized as described herein. The nanowire heterostructures can be in a solution. The kit can optionally include instructional materials teaching the use of the nanowire heterostructure, the collection of a nanowire heterostructures, or junction in the fabrication of a device (e.g., an electronic device, an optoelectronic device, a spintronic device, an optical device, etc.).

This invention also provides an information storage and retrieval system. The system can comprise a nanowire heterostructure as described herein; and a device that detects the nanowire heterostructure and reads the information stored therein. The device can comprise a component such as a microscope, a telescope, an optical system, an image acquisition system, a fluorometer, an emission spectrophotometer, an absorption spectrophotometer, a magnetometer, an atomic force microscope (AFM), a scanning tunneling microscope (STM), a transmission electron microscope, a scanning electron microscope, an elemental analysis instrument (e.g., a reman spectrophotometer), and the like. The system can further comprise a device to synthesize the nanowire heterostructure. In certain embodiments, the system includes an excitation source (e.g. an optical source an IR source, a near IR source, a UV source, a far UV source, a laser, a lamp, an LED, a magnetic field, an electrical field, and the like.) for exciting a signal from the nanowires. In certain embodiments, the detection system does not need to be in contact with the nanowire heterostructure to read the code therein. In particular, by using an appropriate optical system, including but not limited to a lens or telescope, it can be possible to detect and read the code from a large distance away, preferably greater than 1 meter, but optionally less than 1 meter. Detection can even be automatic, with the signal being processed by a computer, and specific instructions delivered as a particular code is detected.

This invention provides a method of storing information. The method can involve encoding information into a format compatible with storage in a nanowire heterostructure as described herein; and preparing a nanowire heterostructure encoding the information. In certain embodiments, the nanowire heterostructure is prepared by a method such as CVD, MOCVD, VLS, and modified VLS. The method can further involve detecting the nanowire and, optionally decoding the nanowire heterostructure to read the coded information. In various embodiments, the decoding can comprise reading an electronic signature, and/or reading an optical signature, and/or reading a magnetic signature, and/or determining an emission spectrum of one or more domains comprising the nanowire heterostructure, and/or determining an absorption spectrum of one or more domains comprising the nanowire heterostructure. The nanowire can be decoded after the nanowire is transported to a new location.

Also provided is a method of transporting information from a first location to a second location. The method involves encoding information at a first location into a format compatible with storage in a nanowire heterostructure as described herein; preparing a nanowire heterostructure encoding the information; transporting the nanowire heterostructure to the second location; and decoding the nanowire heterostructure to read the coded information. The transporting can comprise carrying of the nanowire by a human or a non-human animal, transporting an article (e.g., currency, a weapon, etc) or composition (e.g., currency, a weapon, an explosive, a poison, a biological organism, etc.) comprising the nanowire, and the like. The decoding can be by any of the methods described herein.

A collection of nanowires that have an absorbance or emission signal in the visible region of the electromagnetic spectrum can be detected by eye, as long as the number of wires present produces a signal that is above the detection threshold of the human eye, and above the noise created by any background signal. Nanowires can be made invisible to the human eye by a variety of methods. In one approach, even a large collection of nanowires will be undetectable to the human eye if the optical signals produced do not lie in the visible region of the EM spectrum. For instance, emission from a nanowire that emits light at 1000 nm would by undetectable without a special IR detector. Similarly, if the emission is at 300 nm it would also be undetectable. In many cases, a detectable emission signal in the IR region can be produced without creating a detectable absorbance or emission signal in the visible region.

Another method for making nanowires undetectable by the human eye is to reduce the number of wires so that the signal produced (either visible, IR or UV signal) is below the detection threshold of the human eye in the conditions under which it will be viewed. For instance, an optical signal from a single nanowire would be undetectable by the human eye without a special device or instrument. For instance, nanowires at extremely low density, such that individual nanowires were separated by a distance substantially larger than the diffraction limit of light, embedded in a document or on a surface could be detected using a special single molecule microsope, but would be undetectable otherwise.

In still another embodiment, this invention provides materials and methods for encoding, labeling and tracking items in a manner that is invisible or nearly invisible to the unaided human eye.

In still another embodiment, this invention provides a method of tagging, tracking or identifying an article, a composition, or an animal. The method involves contacting the article, composition or animal with one or more nanowire heterostructures as described herein, whereby a nanowire heterostructure becomes associated with the article composition or animal. The method can then further involve detecting the nanowire heterostructure associated with the article, composition or animal, e.g. as described herein. The nanowire heterostructure can be coded with information indicating a site of origin, of the tagged article. In particular, an invisible nanowire heterostructure can be used (invisible due either to the small quantity or to non-visible optical signals), such that a discrete tag can be provided so that it is difficult to identify that an article, composition or animal has been tagged and/or tracked. In addition, nanowire heterostructures can be incorporated directly into different materials and detected from the outside. In a preferred embodiment, an IR absorbing and emitting nanowire is provided and embedded or included in the inside of an article, composition or animal that does not substantially absorb the wavelengths of light emitted by the nanowire. Such a nanowire can still be detected externally by illuminating the article, composition or animal with an IR optical source, which is transmitted through the article, composition or animal, exciting fluorescence from the nanowire heterostructure, which can then be detected and decoded using an external IR optical system. Such a system preferably encodes nanowires with materials that emit in the wavelength range between about 700 nm and 20,000 nm, preferably between 800 nm and 3000 nm, more preferably between 900 nm and 3000 nm and more preferably 1000 nm and 3000 nm.

This invention also provides a variety of assays (biological, physical, and chemical). One method of detecting an analyte involves contacting the sample with a first binding moiety that binds to the analyte (if present); and detecting a label associated with the analyte wherein the label comprises a nanowire heterostructure as described herein and the detecting indicates the presence and/or identity of the analyte in the sample. The first binding moiety can be a moiety that specifically binds the analyte and the first binding moiety is attached to the label. The first binding moiety can be attached to the label by a linker. In certain embodiments, the first binding moiety binds to and immobilizes the analyte and the analyte is contacted with a second binding moiety that specifically binds to the analyte where the second binding moiety is attached to the label comprising the nanowire heterostructure. In certain embodiments, the first binding moiety binds to and immobilizes the analyte; the analyte is contacted with a second binding moiety that specifically binds to the analyte; and the second binding moiety is contacted with a third binding moiety that specifically binds the second binding moiety, wherein the third binding moiety is attached to the label. The first binding moiety can specifically or non-specifically bind the analyte. Preferred binding moieties used in the assays described herein include, but are not limited to a nucleic acid, an antibody, a polypeptide, a sugar, a lectin, a receptor, a growth factor, a cytokine, a nucleic acid binding protein, and a carbohydrate, a biotin an oligonucleotide, a polynucleotide, an aptamer, an aptazyme, a protein, etc. In certain embodiments, the sample is a biological sample (e.g. cell, a tissue, an organ, urine, blood, plasma, lymph, oral fluid, cerebrospinal fluid, a blood fraction, etc.), a processed biological sample, a pharmaceutical sample, a food sample, an environmental sample, etc. The detecting can comprise decoding the nanowire heterostructure to read the identity of the analyte as described herein.

The assays of this invention are suitable for highly parallel (multiplexed) formats for the detection of a plurality of analytes (e.g. at least 2, preferably at least 5 or 10, more preferably at least 15 or 20, and most preferably at least 25, 50, or 100 different analytes). Using this strategy, it is even possible to detect much larger numbers of analytes, including 1,000 and even 10,000 different analytes. The methods typically involve contacting the sample with a first plurality of binding moieties that specifically or non-specifically bind the target analytes; and detecting a label associated with each species of target analyte, wherein the label comprises a nanowire heterostructure as described herein, the nanowire heterostructure associated with each species of target analyte is distinguishable from the nanowire heterostructures associated with the other target analytes; and the detecting indicates the presence and/or identity of each of the target analytes present analyte in the sample. The first binding moieties can comprise a plurality of different binding moieties each species of which specifically binds to one of the target analytes and each species of which is attached to a label comprising a nanowire heterostructure that uniquely identifies the species in the collection of species. The associated the nanowire heterostructure can uniquely identify the binding moiety associated therewith. The labels are optionally attached to the first binding moieties by linkers. In certain embodiments, the first binding moieties bind to and immobilize the target analytes and the target analytes are contacted with second binding moieties comprising a plurality of binding moiety species where the plurality comprises a collection of species of binding moiety that each specifically bind to one of the target analytes, each species being attached to a to a label comprising a nanowire heterostructure that uniquely identifies the species in the collection of species. In certain embodiments, the first binding moieties bind to and immobilize the target analytes; the target analytes are contacted with second binding moieties second binding moieties comprising a plurality of binding moiety species where the plurality comprises a collection of species of binding moiety that each specifically bind to one of the target analytes; and the second binding moieties are contacted with third binding moieties comprising a plurality of binding moiety species where the plurality comprises a collection of species of binding moiety that each specifically bind to one of the species of second binding moieties, each species of third binding moiety being attached to a to a label comprising a nanowire heterostructure that uniquely identifies the species in the collection of species third binding moieties. The first binding moieties can specifically or non-specifically bind the target analytes. Preferred samples include but are not limited to biological samples, food samples, drug samples, and environmental samples. The nanowire heterostructures can be read and decoded as described herein.

Assays are also provided where the nanowire heterostructure(s) comprise a substrate for the assay. These methods involve providing a first detection element comprising a first nanowire heterostructure as described herein associated with a first specific binding moiety; contacting the binding moiety with the sample whereby the binding moiety specifically binds the first target analyte if the first target analyte is present in the sample; detecting binding of the first target analyte to the first detection element; and reading the information encoded in the nanowire heterostructure to determine the identity of the first target analyte. In this embodiment, detection of the bound analyte can be by detecting a bound label such as a fluorescent dye molecule or quantum dot, an enzyme, a radio-label and the like. In this embodiment, the bound label may act to allow the measurement of the presence and quantity of the analyte present in the sample, while the nanowire heterostructure provides the identitiy of the bound analyte (i.e. it identifies the assay that is being measured on that particular substrate). The method can involve providing at least a second detection element comprising a second nanowire heterostructure as described herein associated with a second specific binding moiety where the second biding moiety binds a target analyte that may or may not be different from the first target analyte; contacting the binding moiety with the sample whereby the second binding moiety specifically binds the second target analyte if the second target analyte is present; detecting binding of the second target analyte to the second detection element; and reading the information encoded in the second nanowire heterostructure to determine the identity of the second target analyte. In certain embodiments, the method uses at least 2, preferably at least about 5 or 10, more preferably at least about 15, 20, or 25, and most preferably at least about 50, 100, or 500 different detection elements. In addition, it is possible to use more than 1000 different detection elements and even 10,000 detection elements. In some embodiments, different detection elements with different binding moieties, specific for different epitopes of the same antigen (e.g. cell, protein, membrane, etc.) can be used to provide additional information about the presence or quantitiy of a specific antigen. For instance, by binding to multiple different epitopes of the same antigen, an assay “fingerprint” can be created in which the ratio of these epitopes within the antigen is measured. This can provide additional information to avoid false-positive detection of an antigen due to a closely related antigen binding to some of the binding moeities. This aspect of the invention is particularly useful in the detection of biological or chemical warfare agents, where false-positive avoidance is critical. In addition, assay fingerprinting can be used to separate specific signal from nonspecific background noise in a bioassay by creating a signature that can be more easily deconvoluted from the noise than just a single peak can. Binding moieties and reading methods preferably include those described herein.

In still another embodiment, this invention provides a method of assembling a device (e.g., a logic circuit, a sensor, a biodetection system, a nano-CHEM-FET array, an electrically addressable device, an optically addressable device, an array, etc.). The method involves providing a collection of nanowire heterostructures as described herein; assembling the nanowire heterostructures into a device; and reading the information encoded in the nanowire heterostructures to determine which nanowire heterostructure is located at which location in the device. The method can involve placing the identity and location of each active nanowire heterostructure in a lookup table. The lookup table can be element of the device, a component of a reader for the device, removable media for the device or the reader, and so forth. The collection of nanowire heterostructures can comprise a plurality of species wherein each species being differently functionalized than the other species comprising the plurality and further wherein the functionalized species is uniquely identified by the information coded into the nanowire heterostructure. The nanowire heterostructures are preferably functionalized as described herein.

In one particularly preferred embodiement, the invention provides an assay system comprising nano-chem-fet detection, in which encoded nanowire heterostructures with particular binding moieties attached to each distinct nanowire heterostructure type are synthesized and funcationlized one at a time, and then mixed into a “master mix” containing all of the detection elements (and therefore all of the assays). These are then randomly assembled into a nanowire array that can be used as a multiplexed nano-CHEM-FET detector. By identifying which detection elements are located between which electrodes, it is possible to create a look-up table to calibrate which nanowire readout goes with which assay.

This invention also provides a method of detecting a label among a plurality of intermingled labels. The method involves providing a plurality of intermingled labels comprising nanowire heterostructures as described herein , wherein each species of nanowire heterostructure encodes a different signature, and decoding the signature of one of the nanowire heterostructures to identify the nanowire heterostructure whereby the label of the nanowire heterostructure is detected and distinguished from other labels comprising the plurality. In this embodiment, there are optionally multiple copies of the same type of nanowire heterostructures within the plurality of intermingled labels, wherein each type of nanowire heterostructure can be detected and distinguished from every other type.

In still another embodiment, this invention provides a method of detecting the contacting or handling of a first composition, article of manufacture, human or non-human animal (herein referred to as a first entity) by a second composition, article of manufacture, human or non-human animal (herein referred to as a second entity). The method involves providing the first entity labeled with one or more of the nanowire heterostructures as described herein; and scanning a second entity suspected of contacting the first entity to detect the nanowire heterostructure, where the presence of the nanowire heterostructure on the second entity indicates that the second entity has contacted the first entity. In an alternative embodiment, nanowires can be functionalized such that they off-gas from the first entity, and can therefore become associated with the second entity without physical contact between the entities. In this case, association of the second entity with the first entity is detected by detecting the presence of the nanowire heterostructure of the first entity on the second entity.

Definitions

A “nanostructure” is a structure having at least one region or characteristic dimension with a dimension of less than 500 nm, e.g., less than 200 nm, less than 100 nm, less than 50 nm, or even less than 20 nm. In many cases, the region or characteristic dimension will be along the smallest axis of the structure. A conductive or semi-conductive nanostructure often displays 1-dimensional quantum confinement, e.g., an electron can often travel along only one dimension of the structure. Examples of nanostructures include nanowires, nanotubes, nanodots, nanorods, nanotetrapods, quantum dots, nanoribbons and the like. A “homonanostructure” is a nanostructure that has an essentially homogeneous arrangement of constituent elements. For example, a homonanowire is a homonanostructure that can be a substantially single crystal structure comprising a base material such as silicon and, optionally, a dopant dispersed in essentially the same manner throughout the crystal. A “heteronanostructure” is a nanostructure that includes subdomains comprising different compositions. For example, a heteronanowire is a heteronanostructure that can be a single crystal structure comprising a base material such as silicon with different subdomains or “segments” having different dopants, or different concentrations of one dopant, or an entirely different material, or any combination thereof. For embodiments that utilize flow alignment, the nanostructures of the invention typically have an aspect ratio greater than 5, typically greater than 10, generally greater than 50, and, optionally, greater than 100 or more.

The term “nanowire” refers to a nanostructure typically characterized by at least one and preferably at least two physical dimensions that are less than about 500 nm, preferably less than about 200 nm, more preferably less than about 150 nm or 100 nm, and most preferably less than about 50 nm or 25 nm or even less than about 10 nm or 5 nm. Nanowires of this invention typically have one principle axis that is longer than the other two principle axes and consequently have an aspect ratio greater than one, more preferably an aspect ratio greater than about 10, still more preferably an aspect ratio greater than about 20, and most preferably an aspect ration greater than about 100, 200, or 500. In certain embodiments, nanowires according to this invention have a substantially uniform diameter such that essentially no (significant) tapering or modulation of the diameter occurs along the length of the nanowire. In particular embodiments, the diameter shows a variance less than about 20%, more preferably less than about 10%, still more preferably less than about 5%, and most preferably less than about 1% over the region of greatest variability and over a linear dimension of at least 5 nm, preferably at least 10 nm,, most preferably at least 20 nm, and most preferably at least 50 nm. Typically the diameter is evaluated away from the ends of the nanowire (e.g. over the central 20%, 40%, 50%, or 80% of the nanowire). In certain embodiments, the nanowires of this invention are substantially crystalline and/or substantially monocrystalline. The nanowires of this invention can be substantially homogeneous in material properties, or in certain embodiments heterogeneous (e.g. nanowire heterostructures) and can be fabricated from essentially any convenient material or materials. The nanowires can comprise “pure” materials, substantially pure materials, be single crystalline, substantially crystalline, non-crystaline, amorphous, crystalline combined with an amorphous or sermiamorphous domain, doped materials and the like and can include insulators, conductors, and semiconductors. Where the nanowires are doped, any particular doped region can act/function as though it is homogeneously doped with respect to its electrical, and/or optical, and/or magnetic, and /or thermal properties. In certain embodiments the nanowires of this invention are essentially one dimensional with respect to electron mobility, e.g. exhibit quantum confinement in two dimensions. Certain nanowires, particularly nanowire heterostructures can comprise one or more domains that are essentially zero-dimensional with respect to electron mobility, e.g. show three-dimensional quantum confinement and act essentially like quantum dots embedded within a quantum wire. Nanowires according to this invention can expressly exclude carbon nanotubes, and, in certain embodiments, exclude “whiskers” or “nanowhiskers”, particularly whiskers having a diameter greater than 100 nm, or greater than about 200 nm. However, many aspects of the present invention can be used to create encoded whiskers to achieve the same encoding goals, but with different materials characteristics than for nanowires. In certain embodiments, the nanowire ranges in length from about 10 nm to about 100 μm, preferably from about 20 nm to about 20 μm, most preferably from about 100 nm to about 10 μm, and most preferably from about 20 nm or 50 nm to about 500 nm. Certain preferred nanowires have a length less than about 1 μm, preferably less than about 500 nm, more preferably less than about 250 nm, and most preferably less than about 100 nm. A “homonanowire” is a nanowire that has an essentially homogeneous arrangement of constituent elements. For example, a homonanowire can be a single crystal structure comprising a base material such as silicon and a dopant dispersed in essentially the same manner throughout the crystal. A “heteronanowire” is a nanowire that includes subdomains comprising different compositions. For example, a heteronanowire can be a single crystal structure comprising a base material such as silicon, with different subdomains or “segments” having different dopants, or different concentrations of one dopant, or both. Examples of nanowires include semiconductor nanowires as described in Published International Patent Application Nos. WO 02/17362, WO 02/48701, and 01/03208, carbon nanotubes, and other elongated conductive or semiconductive structures of like dimensions. Particularly preferred nanowires include semiconductive nanowires, e.g., those that are comprised of semiconductor material selected from, e.g., Si, Ge, Sn, Se, Te, B, Diamond, P, B—C, B—P(BP6), B—Si, Si—C, Si—Ge, Si—Sn and Ge—Sn, SiC, BN/BP/BAs, AlN/AlP/AlAs/AlSb, GaN/GaP/GaAs/GaSb, InN/InP/InAs/InSb, BN/BP/BAs, AlN/AlP/AlAs/AlSb, GaN/GaP/GaAs/GaSb, InN/InP/InAs/InSb, ZnO/ZnS/ZnSe/ZnTe, CdS/CdSe/CdTe, HgS/HgSe/HgTe, BeS/BeSe/BeTe/MgS/MgSe, GeS, GeSe, GeTe, SnS, SnSe, SnTe, PbO, PbS, PbSe, PbTe, CuF, CuCl, CuBr, CuI, AgF, AgCl, AgBr, AgI, BeSiN₂, CaCN₂, ZnGeP₂, CdSnAs₂, ZnSnSb₂, CuGeP₃, CuSi2P₃, (Cu, Ag)(Al, Ga, In, Tl, Fe)(S, Se, Te)₂, Si3N₄, Ge3N₄, Al₂O₃, (Al, Ga, In)₂(S, Se, Te)₃, Al₂CO, and/or an appropriate combination of two or more such semiconductors. In certain aspects, the semiconductor may comprise a dopant from a group consisting of: a p-type dopant from Group III of the periodic table; an n-type dopant from Group V of the periodic table; a p-type dopant selected from a group consisting of: B, Al and In; an n-type dopant selected from a group consisting of: P, As and Sb; a p-type dopant from Group II of the periodic table; a p-type dopant selected from a group consisting of: Mg, Zn, Cd and Hg; a p-type dopant from Group IV of the periodic table; a p-type dopant selected from a group consisting of: C and Si.; or an n-type is selected from a group consisting of: Si, Ge, Sn, S, Se and Te.

The terms “crystalline” or “substantially crystalline”, when used with respect to the nanowires of this invention refer to the fact that the nanowires typically exhibit long-range ordering. The nanowire heterostructures of this invention can bear an oxide, or other coating. In such instances it will be appreciated that the oxide or other coating need not exhibit such ordering (e.g. it can be amorphous or otherwise). In such instances, the phrase “crystalline”, or “substantially crystalline” or substantially “monocrystalline” or “monocrystalline” refer to the central “core” of the nanowire (excluding the coating layers). The terms “crystalline” or substantially crystalline” as used herein are intended to also encompass structures comprising various defects, atomic substitutions and the like as long as the structure exhibits substantial long range ordering.

The term “monocrystalline”, when used with respect to a nanowire of this invention indicates that the nanowire is substantially crystalline and comprises substantially a single crystal.

The terms “heterostructure” or “nanowire heterostructure” when used with reference to nanowires refers to nanowires characterized by at least two different and/or distinguishable material types. Typically one region of the nanowire comprises the first material type, while a second region of the nanowire comprises a second material type. While in certain embodiments, the different material types are distributed radially about the axis of the nanowire, in certain particularly preferred embodiments, the different material types are distributed at different locations along the major axis of the nanowire. In cases of nanowire heterostructures, the transition between material types within the heterostructure can be as sharp as a single atomic layer, or as gradual as a continuous alloy from on end of the nanowire heterostructure to the other. In addition, this transition can be either substantially crystalline, substantially monocrystalline or may comprise defects and dislocations.

The terms “polypeptide”, “peptide” and “protein” are used interchangeably herein to refer to a polymer of amino acid residues. The terms apply to amino acid polymers in which one or more amino acid residue is an artificial chemical analogue of a corresponding naturally occurring amino acid, as well as to naturally occurring amino acid polymers.

The terms “nucleic acid” or “oligonucleotide” or grammatical equivalents herein refer to at least two nucleotides covalently linked together. A nucleic acid of the present invention is preferably single-stranded or double stranded and will generally contain phosphodiester bonds, although in some cases, as outlined below, nucleic acid analogs are included that may have alternate backbones, comprising, for example, phosphoramide (Beaucage et al. (1993) Tetrahedron 49(10): 1925) and references therein; Letsinger (1970) J. Org. Chem. 35:3800; Sprinzl et al. (1977) Eur. J. Biochem. 81: 579; Letsinger et al. (1986) Nucl. Acids Res. 14: 3487; Sawai et al. (1984) Chem. Lett. 805, Letsinger et al. (1988) J. Am. Chem. Soc. 110: 4470; and Pauwels et al. (1986) Chemica Scripta 26: 141 9), phosphorothioate (Mag et al. (1991) Nucleic Acids Res. 19:1437; and U.S. Pat. No. 5,644,048), phosphorodithioate (Briu et al. (1989) J. Am. Chem. Soc. 111 :2321, O-methylphophoroamidite linkages (see Eckstein, Oligonucleotides and Analogues: A Practical Approach, Oxford University Press), and peptide nucleic acid backbones and linkages (see Egholm (1992) J. Am. Chem. Soc. 114:1895; Meier et al. (1992) Chem. Int. Ed. Engl. 31: 1008; Nielsen (1993) Nature, 365: 566; Carlsson et al. (1996) Nature 380: 207). Other analog nucleic acids include those with positive backbones (Denpcy et al. (1995) Proc. Natl. Acad. Sci. USA 92: 6097; non-ionic backbones (U.S. Pat. Nos. 5,386,023, 5,637,684, 5,602,240, 5,216,141 and 4,469,863; Angew. (1991) Chem. Intl. Ed. English 30: 423; Letsinger et al. (1988) J. Am. Chem. Soc. 110: 4470; Letsinger et al. (1994) Nucleoside & Nucleotide 13:1597; Chapters 2 and 3, ASC Symposium Series 580, “Carbohydrate Modifications in Antisense Research”, Ed. Y. S. Sanghui and P. Dan Cook; Mesmaeker et al. (1994), Bioorganic & Medicinal Chem. Lett. 4: 395; Jeffs et al. (1994) J. Biomolecular NMR 34:17; Tetrahedron Lett. 37:743 (1996)) and non-ribose backbones, including those described in U.S. Pat. Nos. 5,235,033 and 5,034,506, and Chapters 6 and 7, ASC Symposium Series 580, Carbohydrate Modifications in Antisense Research, Ed. Y. S. Sanghui and P. Dan Cook. Nucleic acids containing one or more carbocyclic sugars are also included within the definition of nucleic acids (see Jenkins et al. (1995), Chem. Soc. Rev. pp169-176). Several nucleic acid analogs are described in Rawls, C & E News Jun. 2, 1997 page 35. These modifications of the ribose-phosphate backbone may be done to facilitate the addition of additional moieties such as labels, or to increase the stability and half-life of such molecules in physiological environments. In addition, it is possible that nucleic acids of the present invention can alternatively be triple-stranded

As used herein, an “antibody” refers to a protein consisting of one or more polypeptides substantially encoded by immunoglobulin genes or fragments of immunoglobulin genes. The recognized immunoglobulin genes include the kappa, lambda, alpha, gamma, delta, epsilon and mu constant region genes, as well as myriad immunoglobulin variable region genes. Light chains are classified as either kappa or lambda. Heavy chains are classified as gamma, mu, alpha, delta, or epsilon, which in turn define the immunoglobulin classes, IgG, IgM, IgA, IgD and IgE, respectively.

A typical immunoglobulin (antibody) structural unit is known to comprise a tetramer. Each tetramer is composed of two identical pairs of polypeptide chains, each pair having one “light” (about 25 kD) and one “heavy” chain (about 50-70 kD). The N-terminus of each chain defines a variable region of about 100 to 110 or more amino acids primarily responsible for antigen recognition. The terms variable light chain (V_{L}) and variable heavy chain (V_{H}) refer to these light and heavy chains respectively.

Antibodies exist as intact immunoglobulins or as a number of well characterized fragments produced by digestion with various peptidases. Thus, for example, pepsin digests an antibody below the disulfide linkages in the hinge region to produce F(ab)′₂, a dimer of Fab which itself is a light chain joined to V_{H}-C_{H}1 by a disulfide bond. The F(ab)′₂ may be reduced under mild conditions to break the disulfide linkage in the hinge region thereby converting the (Fab′)₂ dimer into a Fab′ monomer. The Fab′ monomer is essentially a Fab with part of the hinge region (see, Fundamental Immunology, W. E. Paul, ed., Raven Press, N.Y. (1993), for a more detailed description of other antibody fragments). While various antibody fragments are defined in terms of the digestion of an intact antibody, one of skill will appreciate that such Fab′ fragments may be synthesized de novo either chemically or by utilizing recombinant DNA methodology. Thus, the term antibody, as used herein also includes antibody fragments either produced by the modification of whole antibodies or synthesized de novo using recombinant DNA methodologies. Preferred antibodies include single chain antibodies (antibodies that exist as a single polypeptide chain), more preferably single chain Fv antibodies (sFv or scFv) in which a variable heavy and a variable light chain are joined together (directly or through a peptide linker) to form a continuous polypeptide. The single chain Fv antibody is a covalently linked V_{H}-V_{L} heterodimer which may be expressed from a nucleic acid including V_{H}- and V_{L}-encoding sequences either joined directly or joined by a peptide-encoding linker. Huston, et al. (1988) Proc. Nat. Acad. Sci. USA, 85: 5879-5883. While the V_{H} and V_{L} are connected to each as a single polypeptide chain, the V_{H} and V_{L} domains associate non-covalently. The first functional antibody molecules to be expressed on the surface of filamentous phage were single-chain Fv's (scFv), however, alternative expression strategies have also been successful. For example Fab molecules can be displayed on phage if one of the chains (heavy or light) is fused to g3 capsid protein and the complementary chain exported to the periplasm as a soluble molecule. The two chains can be encoded on the same or on different replicons; the important point is that the two antibody chains in each Fab molecule assemble post-translationally and the dimer is incorporated into the phage particle via linkage of one of the chains to, e.g., g3p (see, e.g., U.S. Pat. No: 5,733,743). The scFv antibodies and a number of other structures converting the naturally aggregated, but chemically separated light and heavy polypeptide chains from an antibody V region into a molecule that folds into a three dimensional structure substantially similar to the structure of an antigen-binding site are known to those of skill in the art (see e.g., U.S. Pat. Nos. 5,091,513, 5,132,405, and 4,956,778). Particularly preferred antibodies should include all that have been displayed on phage (e.g., scFv, Fv, Fab and disulfide linked Fv (Reiter et al. (1995) Protein Eng. 8: 1323-1331).

An aptamer is an antibody-analogue formed from nucleic acids. An aptazyme is an enzyme analogue, formed from nucleic acids. In particular, an aptazyme can function to change configuration to capture a specific molecule, only in the presence of a second, specific, analyte. Aptamers may not even require the binding of the first label to be detected in some assays, such as nano-CHEM-FET, where the reconfiguration would be detected directly.

The terms “binding partner”, or “capture agent” or “affinity molecule”, or a member of a “binding pair” refers to molecules that specifically bind other molecules to form a binding complex such as antibody-antigen, lectin-carbohydrate, nucleic acid-nucleic acid, biotin-avidin, etc. Such affinity molecules (binding partners) include, by way of example, monomeric or polymeric nucleic acids, aptamers, aptazymes, proteins, polysaccharides, sugars, lectins, and the like (see, e.g., Haugland, “Handbook of Fluorescent Probes and Research Chemicals” (Sixth Edition)), and any of the molecules capable of forming a binding pair as described above.

The phrase “specifically binds” indicates that the molecule binds preferentially to the target of interest or binds with greater affinity to the target (analyte) than to other molecules. For example, an antibody will selectively bind to the antigen against which it was raised. A DNA molecule will bind to a substantially complementary sequence and not to unrelated sequences under stringent conditions. Specific binding can refer to a binding reaction that is determinative of the presence of a the target in a heterogeneous population of molecules (e.g., proteins and other biologics). Thus, under designated conditions (e.g. immunoassay conditions in the case of an antibody or stringent hybridization conditions in the case of a nucleic acid), the specified ligand or antibody binds to its particular “target” molecule and does not bind in a significant amount to other molecules present in the sample.

The terms “hybridizing specifically to” and “specific hybridization” and “selectively hybridize to,” as used herein refer to the binding, duplexing, or hybridizing of a nucleic acid molecule preferentially to a particular nucleotide sequence under stringent conditions. The term “stringent conditions” refers to conditions under which a probe will hybridize preferentially to its target subsequence, and to a lesser extent to, or not at all to, other sequences. Stringent hybridization and stringent hybridization wash conditions in the context of nucleic acid hybridization are sequence dependent, and are different under different environmental parameters. An extensive guide to the hybridization of nucleic acids is found in, e.g., Tijssen (1993) Laboratory Techniques in Biochemistry and Molecular Biology—Hybridization with Nucleic Acid Probes part 1, chapt 2, Overview of principles of hybridization and the strategy of nucleic acid probe assays, Elsevier, N.Y. Generally, highly stringent hybridization and wash conditions are selected to be about 5° C. lower than the thermal melting point (Tₘ) for the specific sequence at a defined ionic strength and pH. The Tₘ is the temperature (under defined ionic strength and pH) at which 50% of the target sequence hybridizes to a perfectly matched probe. Very stringent conditions are selected to be equal to the Tₘ for a particular probe. An example of stringent hybridization conditions for hybridization of complementary nucleic acids which have more than 100 complementary residues on an array or on a filter in a Southern or northern blot is 42° C. using standard hybridization solutions (see, e.g., Sambrook (1989) Molecular Cloning: A Laboratory Manual (2nd ed.) Vol. 1-3, Cold Spring Harbor Laboratory, Cold Spring Harbor Press, NY, and detailed discussion, below), with the hybridization being carried out overnight. An example of highly stringent wash conditions is 0.15 M NaCl at 72° C. for about 15 minutes. An example of stringent wash conditions is a 0.2×SSC wash at 65° C. for 15 minutes (see, e.g., Sambrook supra.) for a description of SSC buffer). Often, a high stringency wash is preceded by a low stringency wash to remove background probe signal. An example medium stringency wash for a duplex of, e.g., more than 100 nucleotides, is 1×SSC at 45° C. for 15 minutes. An example of a low stringency wash for a duplex of, e.g., more than 100 nucleotides, is 4× to 6×SSC at 40° C. for 15 minutes.

The term “test agent” refers to an agent that is to be screened in one or more of the assays described herein. The agent can be virtually any chemical compound. It can exist as a single isolated compound or can be a member of a chemical (e.g. combinatorial) library. In a particularly preferred embodiment, the test agent will be a small organic molecule.

The term “small organic molecule” refers to a molecule of a size comparable to those organic molecules generally used in pharmaceuticals. The term excludes biological macromolecules (e.g., proteins, nucleic acids, etc.). Preferred small organic molecules range in size up to about 5000 Da, more preferably up to 2000 Da, and most preferably up to about 1000 Da.

The phrase “each species in a collection” refers to substantially all species but there may be species excepted or members of species excepted, e.g. due to imperfections in a synthetic protocol.

The term “species” when used with reference to a collection or ensemble refers to each type of entity comprising that ensemble. In an ensemble of nanowire heterostructures species can refer to nanowires differing in their composition (e.g. material composition and/or distribution) or in the moieties with which they are functionalized.

The phrase “each species of coded nanowire is associated with a particular functionality” indicates that there are species of nanowire heterostructure that permit unique identification of each species of functionality present in a collection of functionalities.

The term “electrically coupled” when referring to a nanowire and another moiety (e.g. an electrode, another nanowire etc.) refers to a coupling by which electrons are capable of passing from the nanowire to the other moiety or vice versa or by a change in charge voltage or current in the nanowire induces a change in charge voltage or current in the other moiety or vice versa. The electrical coupling need not require actual physical contact between the nanowire and other moiety. Thus electrical coupling includes, but is not limited to electron tunneling, inductive coupling, and the like.

The term “ohmic, electrical coupling” refers to electrical coupling that shows a substantially linear voltage/current relationship.

The term “optically coupled” refers to a coupling by which a change in optical activity of one moiety induces a change in physical properties (e.g. optical or electronic) in another moiety.

A domain refers to a region of a nanowire that is different and distinguishable from another region of a nanowire. In certain preferred embodiments, a domain refers to a region along the principle axis of the nanowire that is different and distinguishable from a region at another location along a nanowire. Different domains can have different materials and/or physical properties (e.g. conductivity, fluorescence, etc.). Different domains can also be identical in their materials and/or physical properties, but can be distinguished by their location in a nanowire heterostructure.

A “material type” refers to a material that comprises a region of a nanowire heterostructure. Nanowire heterostructures of this invention typically comprise at lest two material types.

A “signature” refers to a particular block of coded information, e.g. a characteristic tag.

A “coding region”, when used with reference to a region of a nanowire refers to a multi-domain region of a nanowire that encodes information and/or that provides a characteristic signature. A nanowire label of this invention can comprise a single coding region (e.g. the entire nanowire can be a coding region) or it can comprise two or more coding regions.

A “substantially uniform diameter” when used with respect to a nanowire refers to a diameter that shows a variance less than about 20%, more preferably less than about 10%, still more preferably less than about 5%, and most preferably less than about 1% over the region of greatest variability in the nanowire and over a linear dimension of at least 5 nm, preferably at least 10 nm,, most preferably at least 20 nm, and most preferably at least 50 nm. Typically the diameter is evaluated away from the ends of the nanowire (e.g. over the central 20%, 40%, 50%, or 80% of the nanowire).

The “diameter of a nanowire” refers to the diameter of a cross-section normal to the major principle axis of the nanowire. Where the cross-section is not circular, the diameter is the average of the major and minor axes of that cross-section.

The term “substantially monodisperse distrbibution of diameters” refers to a population of nanowires wherein the distribution of diameters within the population has a coefficient of variance of less than about 75%, preferably less than about 50%, more preferably less than about 25%, more preferably less than about 10% and most preferably around 5%.

The phrase “active nanowire heterostructure” refers to a nanowire heterostructure that is incorporated into a circuit and/or device that that forms a functioning component of that circuit or device.

A nanowire heterostructure is “linked” or “conjugated” to, or “associated” with, a specific-binding molecule or member of a binding pair when the nanowire heterostructure is chemically coupled to, or associated with the specific-binding molecule. Thus, these terms intend that the nanowire heterostructure may either be directly linked to the specific-binding molecule or may be linked via a linker moiety, such as via a chemical linker described herein. The terms indicate items that are physically linked by, for example, covalent chemical bonds; physical forces such van der Waals or hydrophobic interactions, encapsulation, embedding, or the like. As an example without limiting the scope of the invention, nanowire heterostructure can be conjugated to molecules that can interact physically with biological compounds such as cells, receptors, proteins, nucleic acids, subcellular organelles and other subcellular components. For example, nanowire heterostructure can be associated with biotin which can bind to the proteins, avidin and streptavidin, neutravidin, and the like. Also, nanowire heterostructure can be associated with molecules that bind nonspecifically or sequence-specifically to nucleic acids (DNA RNA). As examples without limiting the scope of the invention, such molecules include small molecules that bind to the minor groove of DNA (for reviews, see Geierstanger and Wemmer (1995) Ann. Rev. Biophys. Biomol. Struct. 24: 463-493; and Baguley (1982) Mol. Cell. Biochem 43: 167-181), small molecules that form adducts with DNA and RNA (e.g. CC-1065, see Henderson and Hurley (1996) J. Mol. Recognit. 9: 75-87; aflatoxin, see Garner (1998) Mutat. Res. 402: 67-75; cisplatin, see Leng and Brabec (1994) IARC Sci. Publ. 125: 339-348), molecules that intercalate between the base pairs of DNA (e.g. methidium, propidium, ethidium, porphyrins, etc., for a review see Bailly et al. J. Mol. Recognit. 5: 155-171), radiomimetic DNA damaging agents such as bleomycin, neocarzinostatin and other enediynes (for a review, see Povirk (1996) Mutat. Res. 355: 71-89), and metal complexes that bind and/or damage nucleic acids through oxidation (e.g. Cu-phenanthroline, see Perrin et al. (1996) Prog. Nucleic Acid Res. Mol. Biol. 52: 123-151; Ru(II) and Os(II) complexes, see Moucheron et al. (1997) J. Photochem. Photobiol. B 40: 91-106; chemical and photochemical probes of DNA, see Nielsen (1990) J. Mol. Recognit. 3: 1-25.

As used herein, a “biological sample” refers to a sample of isolated cells, tissue or fluid, including but not limited to, for example, plasma, serum, spinal fluid, semen, lymph fluid, the external sections of the skin, respiratory, intestinal, and genitourinary tracts, tears, saliva, milk, blood cells, tumors, organs, and also samples of in vitro cell culture constituents (including but not limited to conditioned medium resulting from the growth of cells in cell culture medium, putatively virally infected cells, recombinant cells, and cell components). A biological sample can also include a processed and prepared biological sample for a bioassay, comprising additional elements such as buffers, detergents and the like.

The term “monochromatic”., when used with reference to an emission spectrum, indicates that the emission spectrum comprises a single emission peak with a full-width-at-half-maximum of preferably less than 100 nm, more preferably less than 50 nm, and more preferably less than 30 nm.

The term “detectable substance” refers to a molecule or other entity or group, the presence, or absence, or quantity of which in a material such as a biological material, is to be ascertained by use of, for example, an assay as described herein.

The term “affinity molecule” refers to a molecule or group of molecules that will selectively bond to a detectable substance (if present) in the material (e.g., biological material) being analyzed.

By use of the term “linking agent” is meant a substance capable of linking with a semiconductor nanocrystal and also capable of linking to an affinity molecule.

The terms “link” and “linking” are meant to describe the adherence between the affinity molecule and the semiconductor nanocrystals, either directly or through a moiety identified herein as a linking agent. The adherence may comprise any sort of bond, including, but not limited to, covalent, ionic, hydrogen bonding, Van der Waals' forces, or mechanical bonding, etc.

The terms “bond” and “bonding” are meant to describe the adherence between the affinity molecule and the detectable substance. The adherence may comprise any sort of bond, including, but not limited to, covalent, ionic, or hydrogen bonding, Van der Waals' forces, or mechanical bonding, etc.

### BRIEF DESCRIPTION OF THE DRAWINGS

FIG. 1 illustrates a comparison of an information-encoded nanowire heterostructure of this invention with a Universal Product Code.

FIG. 2 illustrates the use of two material types to create two or three domains in a single nanowire heterostructure.

FIG. 3 illustrates positional encoding of information in a nanowire heterostructure.

FIG. 4 illustrates encoding of information in domain lengths in a nanowire heterostructure.

FIG. 5 illustrates encoding of information in domain lengths and positions in a nanowire heterostructure. In certain embodiments, the change in length can be below the quantum-confinement limit, between the quantum confinement limit and the diffraction limit or above the diffraction limit. In the first case, the change in length results in a change in color, in the second it produces a change in intensity (because there is more material emitting), and in the third case, it results in longer fluorescent segments). Each of these properties can be used as a coding element.

FIG. 6a and 6B provide a schematic illustration of a device for fabrication a nanowire heterostructure and illustrate the growth mechanism of such a heterostrucutre. FIG. 6A illustrates a fabrication device. FIG. 6B) shows different stages of the block-by-block nanowire growth process: (1) alloying process between Au thin film and Si species in substrate/vapor; (2) growth of pure Si block when the laser is off, only Si species deposit into the alloy droplet; (3) growth of SiGe alloy block when the laser is on, both Si and Ge species deposit into the liquid droplet; (4) growth of Si/SiGe superlattice structure by turning on and off the laser beam periodically

FIG. 7 shows a schematic illustration of the use of encoded nanowire heterostructures (tags) to identify individual members of a combinatorial library made by the “mix and split” method.

FIG. 8 illustrates the creation and use of an affinity reagent utilizing the nanowire heterostructures of this invention as tags (labels). The nanowire heterostructure is functionalized with a linking agent (e.g. a linker) to product a functinalized nanowire heterostructure that can then readily be joined to an affinity molecule (e.g. an antibody) to product an affinity reagent (nanowire heterostructure probe) specific for a target analyte. The affinity reagent can then be used to bind and detect and/or quantify and/or immobilize the target analyte, e.g. in a particular sample.

FIG. 9 illustrates the creation of a collection of nanowire heterostructures comprising particular pre-defined codes. Nanostructures comprising each code are synthesized separately and then combined to provide a complex collection comprising a plurality of different codes.

### DETAILED DESCRIPTION

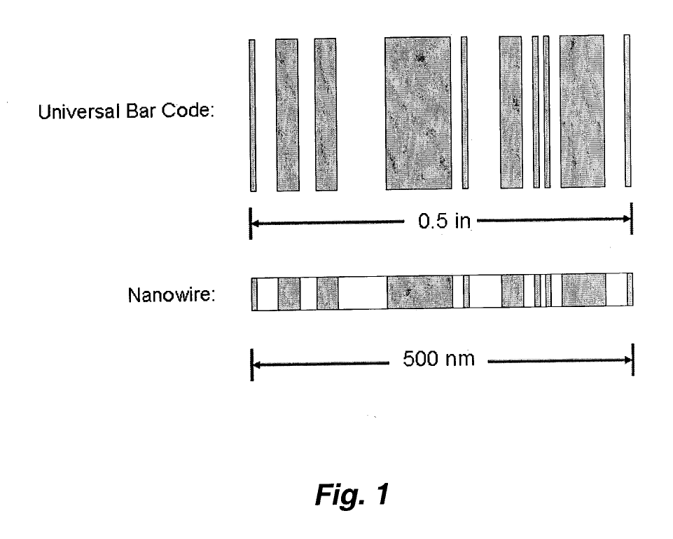

This invention pertains to novel methods and compositions for encoding information. The methods utilize nanowire heterostructures (e.g. nanowires comprising at least two different and distinguishable materials (material types). The spatial disposition and/or material characteristics of regions comprising particular material types along the length of the nanowire can be used to encode information much the way the “universal bar code” encodes information in a particular distribution of stripes and intervening spaces along a “read” path (see, e.g., FIG. 1). Nanowires, however typically store such information in a much smaller spatial scale. Indeed, such nanowires can be virtually undetectable to the naked eye.

The nanowire heterostructures coded with information find used in a wide variety of applications. For example, in one embodiment, this invention provides methods of transporting information from a first location to a second location. The methods can involve encoding information at a first location (or derived from a first location) into a format compatible with storage in a nanowire heterostructure as described herein, preparing a nanowire heterostructure encoding the information; transporting the nanowire heterostructure to said second location; and decoding the nanowire heterostructure to read the coded information.

In another embodiment, the nanowire heterostructures of this invention can be used to tracking or identifying an article, a composition, or an animal. In these applications, the article, composition or animal is contacted with one or more nanowire heterostructures as described herein so a nanowire heterostructure becomes associated with the article composition or animal. The nanowire heterostructure associated with said article, composition or animal is then optionally detected, e.g. at a later time when the goods, person, composition or article of manufacture is recovered. Optinally, the nanowire heterostructures can be consumed by or embedded within the composition, article of manufacture of animal, and can exist homogeneously or inhomogeneously distributed therewithin. Such methods can be used to identify site of origin or manufacturer of the composition (e.g. toxin, drug, explosive, etc.) or article of manufacture (e.g. weapon, currency, etc.), of the animal or plant (e.g. transgenic crop), or composition (e.g. explosive, toxin, etc. Such methods can also be used to verify authenticity of important documents or valuable items, or can be used to discretely label an entity by using invisible nanostructure heterostructures.

In still other embodiments, the nanowire heterostructure encoding information can be used as tags in various assays for the detection and/or quantitation of one or more analytes. Because the labels are readily detectable and distinguishable and have a sufficiently high data storage capacity so that large numbers of distinguishable labels are readily produced, they are of particular use in highly parallel (multiplexed) assays.

The nanowire heterostructures of this invention can also be used in microfabrication procedures. The labels can be used to tag specific elements (e.g. particular functionalized nanowires). The elements are assembled into a device, and by reading the location of nanowire heterostructure in the assembled device, the address of the labeled elements can be precisely determined.

These uses are merely illustrative and not meant to be limiting. Using the teaching provided herein, one of skill in the art can readily develop numerous other uses for the information-encoding nanowire heterostructures of this invention.

I. Encoding Information into Nanowire Heterostructures.

In certain embodiments, this invention pertains to methods of encoding information into nanowire heterostructures and uses of such encoded information structures. The nanowire heterostructures of this invention comprises at least two different materials (material types), typically distributed at one or more locations along the length of the nanowire that delineate two or more different and distinguishable domains. Information can be encoded in the material characteristics of the domains, and/or the size of the domains, and/or the location of the domains.

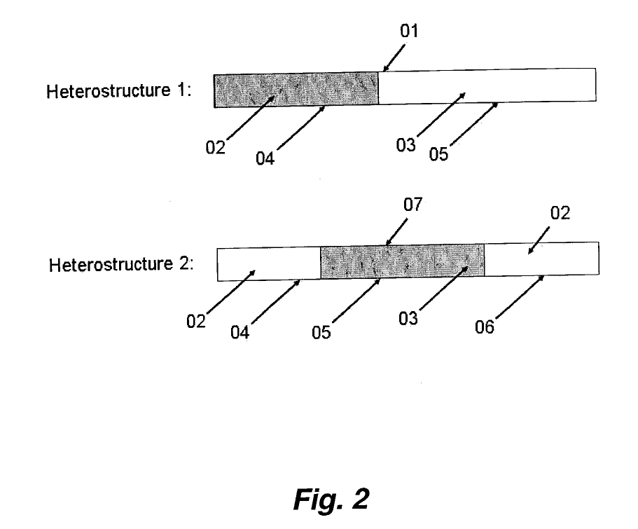

FIG. 2 illustrates two a simple nanowire heterostructure (01 and 07) comprising two materials, a first material 02 and a second material 03 . In heterostructure 1 (01), because the first material 02 is located at the end of the nanowire heterostructure, the combination of the first and second material delineates two domains: a first domain 04, and a second domain 05. In the second heterostructure 07, the first material 02 is located away from the end of the nanowire and three different and distinguishable domains are delineated: a first domain 04, a second domain 05, and a third domain 06. It is noted that in this example (heterostructure 2), two domains (domain 04 and 06) are of the same material type 02 , but nevertheless are different and distinguishable.

Information can be encoded in the domains by a variety of methods including, but not limited to encoding by location of the various domains along the nanowire heterostructure, and/or by the length of various domains along the nanowire heterostructure, and/or by the combination of position and length of various domains along the nanowire, and/or by the physical properties of the domains (e.g., electrical properties, magnetic properties, color, emission spectra, absorption spectra, fluorescence, etc.). In certain embodiments, a repeating code is encoded in the nanowire so that if the wire is destroyed into smaller parts the code will still exist.

A) Spatial Encoding.

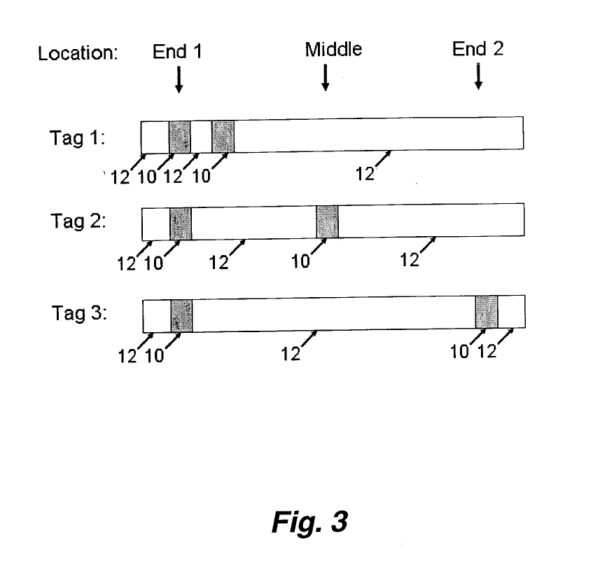

FIG. 3 illustrates encoding of information by the location of domains along the nanowire heterostructure. This figure illustrates three nanowire heterostructures (designated Tag 1, Tag 2, and Tag 3). Each nanowire heterostructure comprises two domains 10, that are identical to each other, but vary in their location along the nanowire. The tags can be distinguished by simply by the differences in location of the 10 domains. Thus, for example, tag 1 has both domains 10 near end 1. Tag 2 has one domain 10 near end 1 and the second domain 10 at or near the middle of the heterostructure. Tag 3 has one domain 10 near each end of the heterostructure. The three tags are clearly different and distinguishable and thus encode different information. In this example, the information could also be encoded in the three domains 12 and the three tags can then be distinguished by the relative widths of the three domains 12.

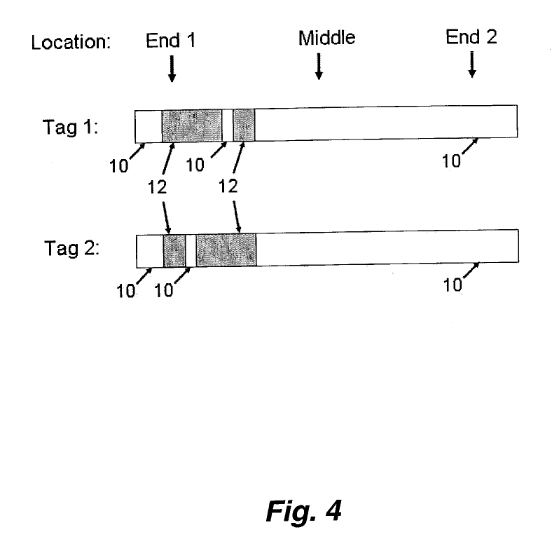

An example of encoding information in the length of the various domains is illustrated in FIG. 4. In this example, the three domains 10 are identical in both heterostructures. The two domains 12 occupy essentially the same region of the two nanowire heterostructures, however, in the first heterostructure (Tag 1), the leftmost domain 12 is thicker than the other domain 12, while in the second heterostructure (Tag 2), the leftmost domain 12 is thinner than the other domain 12. Again, the two tags are readily distinguished and can represent different encoded information. It is noted that in this case, the information could also be regarded as encoded in the positions of the two domains 12, i.e. the location of the thinner domain 12, as compared to the location of the thicker domain 12 .

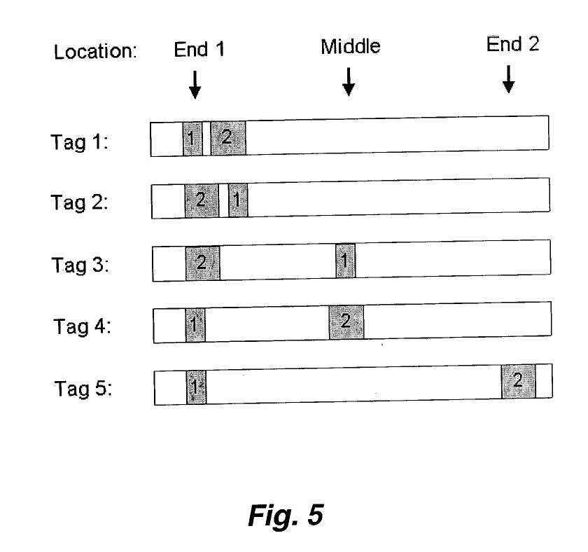

Information can be encoded in both the length and distribution of various domains comprising the nanowire heterostructure. This is illustrated in FIGS. 1 and 5. Such an encoding system, exploiting both location and width of domains is analogous to a universal bar code and provide effective “high level” encoding of information. The use of both domain location and domain length dramatically increases the density of information storage. Thus, as illustrated in FIG. 5, the use of 2 different domain lengths and (designated a 1 and 2 in FIG. 5), and 3 domain locations provides 5 different and distinguishable states (tags) (e.g., a system that stores 5 bits of information). Of course FIG. 5 is a simple case for the purposes of illustration. In fact, a nanowire heterostructure spatial barcode does not need to be based on a binary code, but can comprise analog variations in widths and spacings. As with the Universal Product Code, this can provide an enormous number of available codes. A single nanowire heterostructure can comprise a large number (e.g. greater than about 10, preferably greater than about 20 or 50, more preferably greater than about 100 or 500, and most preferably greater than about 1000 or 5000) of different and distinguishable domains at a similar large number of locations permitting the storage of large amounts of information and/or the creation of a large number of different and distinguishable nanowire heterostructures.

B) Information Encoded in Material/domain Type.

In the previous examples, the various domains are delineated by two material types; a first material and a second material. To encode information, the material types are sufficient where they are simply capable of delineating domains.

In certain embodiments, however, information can be encoded in the physically properties of the materials used in the heterostructure. Thus, for example, domains can be delineated within the nanowire that show certain electrical characteristics (capacitance, conductivity, impedance, etc.), and/or certain magnetic characteristics (e.g. spin), and/or certain optical characteristics (e.g. fluorescent signatures, colors, absorption spectra, etc.).

With three different domain types (e.g. a red domain, a blue domain, and a green domain) at fixed locations on the nanowire heterostructure, it is possible to readily encode 5 bits of information (note an RRG pattern may not be distinguishable from a GRR pattern) (see, e.g., Table 1).

TABLE 1
Encoding of 5 bit into three domains.

| Bit | Domain 1 | Domain 2 | Domain 3 |
|---|---|---|---|
| 000 | R | R | R |
| 001 | R | R | G |
| 011 | R | G | R |
| 100 | R | G | G |
| 101 | G | R | G |
| 110 | G | G | G |

Adding more distinguishable features, e.g. fluorescence intensity, length of the domain, spatial location of the domain, differential doping, etc., dramatically increases the information storage.

Thus, for example, by providing N domains each having M distinguishable states resulting from the selection of materials used to fabricate the domain and/or the length and/or diameter of the domain, or from different intensities resulting from a particular discrete optical transition, Mⁿ different states can be uniquely defined. In the case wherein M is 2, in which the two states could be the presence or absence of a particular domain, the encoding scheme would thus be defined by a base 2 or binary code. In the case wherein M is 3, in which the three states could be the presence of a domain at two distinguishable intensities and/or emission colors, and/or lengths, etc and their absence, the encoding scheme would be defined by a base 3 code. Herein, such base M codes wherein M is greater than 2 are termed higher order codes. The advantage of higher order codes over a binary order code is that fewer identifiers are required to encode the same quantity of information.

The ability to develop a higher order encoding system is dependent upon the number of different intensities domains and states capable of detection by both the hardware and the software utilized in the decoding system. In particularly preferred embodiments, each discrete emission or color, is capable of being detectable at two to twenty different intensities. In one such embodiment wherein eleven different states (e.g. domain lengths/intensities) are available, it is possible to employ a base 11 code. Alternatively, in certain preferred embodiments, a discrete emission color is capable of being detected with a peak wavelength defined within, e.g. 1 nm, providing an even greater increase in the coding density. By using the effects of quantum confinement on the size/length scale below about 10 nm, it is possible to use small changes in the length of a fluorescent segment to finely adjust the peak emission wavelength, as well as the absorbance characteristics of the section. Using this method, it is possible to create finely controlled spectral codes.

Clearly, the advantages of the nanowire heterostructures of this invention, namely the ability to provide discrete states (e.g. discrete optical transitions at a plurality of intensities) at particular locations in an extraordinarily small structure provides a powerful and dense encoding scheme that can be employed in a variety of disciplines.

As indicated above, the nanowire heterostructure of this invention can act as a barcode, wherein a plurality of the domains characterizing the nanowire heterostructure produces a distinct emissions spectrum. These characteristic emissions can be observed as colors, if in the visible region of the spectrum or can be invisible (e.g. if emitting in the infra-red range of the spectrum).

In certain embodiments, various domains encoding information need not be spatially resolved. For example, a nanowire heterostructure can be fabricated comprising three different domains each having a different florescence wavelength where the three domains are spaced close enough together that they cannot be spatially resolved. Thus, in various embodiments, coding region can be on the order of the wavelength of the longest wavelength emitter, less than about half the wavelength of the light being emitted or less than about 300 nm (preferably less than about 250 nm, more preferably less than about 200 nm), or less than the diffraction limit of light, etc. Such a coding region would provide an emission spectrum (intensity and wavelength) that is a combination of the emission spectra of each domain comprising the region. Thus, a single region might provide a polychromatic (multi-modal) spectrum (e.g., it might have multiple peaks from a single region). One or a plurality of such multi-modal domains can exist in a single heterostructure. Thus, this invention contemplates codes in which there are several fluorescent regions within a single diffraction limit that are separated from several other sub-diffraction limited segments by a longer segment to provide a spatial barcode in which each fluorescent spot of the spatial code contains a complete spectral code and thereby provides even higher coding density. It is also possible to an entirely spectral code, comprising a nanowire heterostructure where the entire code is contained in a sub-diffraction limited space. In this case, all of the coding information is contained within the spectral component of the heterostructure.

The foregoing coding schemes are merely illustrative and not intended to be limiting. Using the teaching provided herein, one of skill in the art can readily implement numerous other coding schemes in nanowire heterostructures.

II. Reading Codes Embedded in Nanowires.

The codes embedded in the nanowire heterostructures of this invention can be read by any of a wide variety of methods. In one simple approach, where the domains comprising the nanowire heterostructure are visually distinguishable, the nanowire heterostructure is simply read by visual inspection. The visual inspection, can be direct, but more typically will be by the use of a magnification system, (e.g. magnifying glass, microscope, and the like). As an example, a simple code could be a (red+green) heterostructure, that would appear orange to the eye, and a (red+green+blue) heterostructure, which would appear white to the eye, and be easily distinguishable from the first code.

In the case of nanowire heterostructures encoding information in fluorescent domains, the code can often be read and decoded by the use of a fluorescence microscope (directly read or analyzed with an image analysis system), a fluorimeter, or, in some embodiments, a fluorescence cell sorter (FACS), and the like.

In certain embodiments, the nanowire heterostructure will encode information in properties not detectable to the naked eye a detector can be used to acquire/record the nanowire heterostructure signal. The selection of an appropriate detection device will depend on the manner in which information is encoded in the nanowire heterostructure. Thus, for example, where one or more domains emit in the infra-red (e.g. near infra-red, far infra red, etc.) an infra-red detector (e.g. a CCD device) can be used to read the information encoded in the heterostructure. Where the information is encoded in magnetic properties of the domains comprising a nanowire heterostructure, a magnetometer can be used to read the encoded information. Various suitable devices for reading encoded information include, but are not limited to a microscope, a telescope, an optical system, an image acquisition system, a fluorometer, an emission spectrophotometer, an absorption spectrophotometer, a magnetometer, an atomic force microscope (AFM), a scanning tunneling microscope (STM), an ammeter, a voltmeter, an ohmmeter, a field strength meter, a transmission electron microscope, and a scanning electron microscope.

Nanowire heterostructures that contain only spectral information within the visible range can be “decoded” by eye, or with a simple visible-light spectrometer. Codes in the UV or IR require appropriate spectroscopic detection equipment (UV or IR spectrometer). Codes that include spatial information, or spectral-only, but at such a low concentration that individual wires are separated by several microns, typically involves the use of an optical microscope with a magnification and numerical aperture matched to the size and resolution of the coding pattern (as will be understood). Precise spectral and spatial information can be obtained through the use of a spectral imaging system such as a microscope with an automated and calibrated filter wheel, a liquid-crystal tunable filter, or the like.

It will be noted that transmission electron microscopy, scanning electron microscopy, scanning tunneling microscopy (STM), atomic force microscopy (AFM) and the like can be used to “directly” detect differences in material composition along the length of the nanowire heterostructure. When such readout methods are used, the domains comprising the nanowire heterostructure need produce no detectable signal.

Where the information is not spatially encoded in the nanowire heterostructure the information encoded in the heterostructure can often be read and decoded without any microscopic examination. Thus, for example, a signal can be encoded in a fluorescent signal by the emission intensity at each emission wavelength. In this instance the nanowire heterostructure can readily and rapidly be read using an emission spectrophotometer.

In certain embodiments, even spatially encoded information can be read without microscopic examination. For example, where the information is stored in relative length and/or order of various domains and the domains differ in absorption or reflectance a scanning laser system can be used to rapidly read the encoded information, much the way a supermarket scanner reads a universal bar code.

In certain embodiments, the detector/detection means can be incorporated into an integrated system. An example of one specific system for automated detection for use with nanowire heterostructures encoding information in the optical properties of the heterostructure (e.g. in fluorescent properties) can include, but is not limited to, an imaging scheme comprising an excitation source, a monochromator (or any device capable of spectrally resolving the image, or a set of narrow band filters) and a detector (e.g. a detector array). In one embodiment, the apparatus consists of a blue or UV source of light, of a wavelength shorter than that of the fluorescence to be detected. This can be broadband UV light source, such as a deuterium lamp with a filter in front; the output of a white light source such as a xenon lamp or a deuterium lamp after passing through a monochromator to extract out the desired wavelengths; or any of a number of continuous wave (cw) gas lasers, including but not limited to any of the Argon Ion laser lines (457, 488, 514, etc. nm), a HeCd laser; solid state diode lasers in the blue such as GaN and GaAs (doubled) based lasers or the doubled or tripled output of YAG or YLF based lasers; or any of the pulsed lasers with output in the blue, to name a few.

The fluorescence from the nanowire heterostructure can be passed through an imaging subtracting double monochromator (or two single monochromators with the second one reversed from the first), for example, consisting of two gratings or prisms and a slit between the two gratings or prisms. The monochromators or gratings or prisms can also be replaced with a computer controlled color filter wheel where each filter is a narrow band filter centered at the wavelength of emission of one of the dots. The monochromator assembly has more flexibility because any color can be chosen as the center wavelength. Furthermore, a CCD camera or some other dimensional detector can record the image(s), and software color codes that image to the wavelength chosen above. The system then moves the gratings to a new color and repeats the process. As a result of this process, a set of images of the same spatial region is obtained and each is color-coded to a particular wavelength that is needed to analyze the data rapidly.

In another embodiment, the apparatus is a scanning system as opposed to the above imaging scheme. In a scanning scheme, the sample to be analyzed is scanned with respect to a microscope objective. The fluorescence is put through a single monochromator or a grating or prism to spectrally resolve the colors. The detector is a diode array that then records the colors that are emitted at a particular spatial position. The software then ultimately recreates the scanned image and decodes it.

III. Fabricating Nanowire Heterostructures Comprising Encoded Information.

A) Domains and Domain Properties of Nanowire Heterostructures.

The nanowire heterostructures of this invention comprising at least a first material type and a second material type where said first material type and said second material type delineate at least two different and distinguishable domains that store coded information. The domains comprising the nanowire heterostructure can be selected to have particular physical properties. Thus, ,for example adjacent domains can be n-doped and p-doped, , respectively and provide a junction having particular electro and/or electrooptical properties. In certain embodiments, the material types, nanowire size and domain lengths can be created that effectively bound a particular (e.g. semiconducting) domain with adjacent domains comprising higher bandgap materials. The quantum confinement thus produced can result in a fluorescent and/or electroluminescent domain. In certain embodiments, material type and/or nanowire dimensions can be selected that produce domains having characteristic colors or absorption spectra, or magnetic properties and the like.

The nanowire heterostructures of this invention can be fabricated of any of a number of convenient materials, the selection of materials being dependent on the encoding scheme and the properties that are to be conferred on particular domains comprising the nanowire heterostructure. In certain embodiments, the nanowires are fabricated of materials comprising elements of groups II, III, IV, V, and VI of the periodic table or of combinations thereof. Particularly preferred nanowire heterostructures include semiconducting nanowire heterostructures. Semiconductors for use in the nanowire heterostructures of this invention include but are not limited group II-VI, III-V and group IV semiconductors such as ZnS, ZnSe, ZnTe, CdS, CdSe, CdTe, MgS, MgSe, MgTe, CaS, CaSe, CaTe, SrS, SrSe, SrTe, BaS, BaSe, BaTe, GaN, GaP, GaAs, GaSb, InP, InAs, InSb, AlS, AlP, AlSb, PbS, PbSe, Ge and Si and ternary and quaternary mixtures thereof.

The domains characterizing nanowire heterostructures of this invention can fabricated to obtain particular physical properties. Thus, for example, nanowire heterostructures can be fabricated with particular domains exhibiting certain predetermined electrical properties (e.g. conductivity, impedance, etc.), certain magnetic properties, certain optical properties (e.g., color, emission spectra, absorption spectra, etc.), and the like.

In certain particularly preferred embodiments, the nanowire heterostructure domains are characterized by particular optical properties including, but not limited to detected/read by color, emission spectra, absorption spectra, intensity, and the like.

The composition of the domain(s) comprising a nanowire heterostructure, as well as the size of the domain(s) (e.g. length and/or diameter) affect the characteristic spectral emission wavelength of domains. Thus, a domain of a nanowire heterostructure comprising e.g., a semiconductor as listed above will be selected based upon the desired spectral characteristics desired. For example, semiconductor materials, that at certain size range emit energy in the visible range include, but are not limited to, CdS, CdSe, CdTe, ZnSe, ZnTe, GaP, and GaAs. Semiconductor materials that can emit energy in the near IR range include, but are not limited to, InP, InAs, InSb, PbS, and PbSe. Semiconductor materials that can emit energy in the blue to near-ultraviolet include, but are not limited to, ZnS and GaN.

To prepare a nanowire heterostructure storing encoded information in an “optical format”, it is possible to tune the emission of various domains comprising the heterostructure to a desired wavelength by controlling the diameter of the nanowire heterostructure and/or the length of the domain(s) in question and/or the nature of the materials bordering the domain(s). Tuning of nanowire heterostructure domains is analogous to the tuning of emission spectra of nanocrystals (quantum dots) (see, e.g., U.S. Pat. Nos. 6,048,616; 5,990,479; 5,690,807; 5,505,928; 5,262,357, as well as PCT Publication No. 99/26299).

The color of light produced by a particular size, size distribution and/or composition of a semiconductor nanocrystal can be readily calculated or measured by methods that are known to those skilled in the art. As an example of these measurement techniques, the bandgaps for nanocrystals of CdSe of sizes ranging from 12 Å to 115 Å are given in Murray et al. (1993) J. Am. Chem. Soc. 115:8706. These techniques allow ready calculation of an appropriate size, size distribution and/or composition of semiconductor nanocrystals and choice of excitation light source to produce a nanocrystal capable of emitting light device of any desired wavelength. Analogous methods can be used to determine domain properties of a nanowire heterostructure.

In certain embodiments, the surface of the nanowire heterostructure can be modified to enhance the efficiency of the emissions, by adding an overcoating layer to the nanowire. The overcoating layer can be used to mitigate adverse effects caused by defects at the surface of the nanowire that can result in traps for electrons or holes that degrade the electrical and optical properties of the material. An insulating layer at the surface of the nanowire can provide an atomically abrupt jump in the chemical potential at the interface that eliminates energy states that can serve as traps for the electrons and holes. This results in higher efficiency in the luminescent process.

Suitable materials for the overcoating layer include semiconductor materials having a higher bandgap energy than the semiconductor nanowire core. In addition to having a bandgap energy greater than the semiconductor nanowire core, suitable materials for the overcoating layer can have good conduction and valence band offset with respect to the core semiconductor nanowire. Thus, the conduction band is desirably higher and the valence band is desirably lower than those of the core semiconductor nanowire. For semiconductor nanowire domains that emit energy in the visible (e.g., CdS, CdSe, CdTe, ZnSe, ZnTe, GaP, GaAs) or near IR (e.g., InP, InAs, InSb, PbS, PbSe), a material that has a bandgap energy in the ultraviolet regions can be used. Exemplary materials include ZnS, GaN, and magnesium chalcogenides, e.g., MgS, MgSe, and MgTe. For a semiconductor nanowire core that emits in the near IR, materials having a bandgap energy in the visible, such as CdS or CdSe, can also be used.

Just as overcoating layers can improved emission obtained from various domains comprising a nanowire heterostructure of this invention, so to can higher bandgap energy regions bounding a lower bandgap energy region within the nanowire heterostructure provides improved fluorescence emission intensity and/or provide “blank regions” that delineate separate domains.

B) Nanowire Heterostructure Fabrication.

The nanowire heterostructures encoding information can be fabricated by any of a number of convenient methods. Suitable approaches to the highly controlled fabrication of nanowire heterostructures are described by Gudiksen et al. (2001) Nature, 415: 617-620; Wu et al. (2002) Nano Letters, 2(2): 83-86; and by Björk et al. (2002) Nano Letters, 2(2): 87-89).

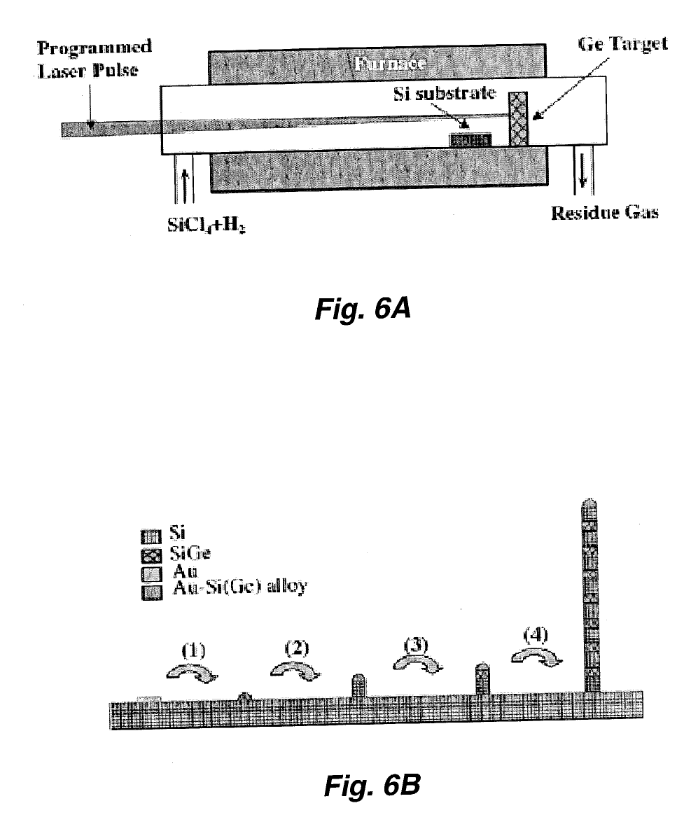

In the method described by Wu et al. a modified pulsed laser ablation/chemical vapor deposition (PLA-CVD) process is used to produce nanowire heterostructures. This method is illustrated by FIGS. 6A and 6B. In the example illustrated in these figures, a (111) Si wafer coated with a thin layer of Au is put inside a quartz furnace tube as substrate. A gas mixture of H₂ and SiCl₄ is continuously introduced into the reaction tube. Nanowire growth is via a modified vapor-liquid-solid (VLS) mechanism (FIG. 6B) with gold as solvent at high temperature.

This process starts with the dissolution of gaseous reactants in nanosized liquid droplets of the metal solvent, followed by nucleation and growth of single crystalline wires (FIG. 6B). Accurate compositional profile and interface control at the nanometer or even atomic level while maintaining a highly crystalline and coherent interface along the wire axis. is made possible through successive feed-in of different vapor sources. To synthesize, e.g. Si/SiGe superlattice nanowires, Ge vapor is generated in pulsed form through the pulsed ablation of a pure Ge target with a frequency-doubled Nd:YAG laser (wavelength 532 nm, 6 Hz, power density 10 J/cm2 per pulse). The reaction temperature typically ranges from 850° C. to 950° C. At this temperature, a gold thin film forms a liquid alloy with silicon and spontaneously breaks up into nanometer-sized droplets (FIG. 6B (1)). Silicon species continuously deposit into Au-Si alloy droplets where the Si nanowire growth is initiated upon supersaturation (FIG. 6B (2)). During this growth process, if the laser is turned on, Ge vapor is be generated and both Ge and Si species are deposited into the alloy droplets. The SiGe alloy then precipitates from the solid/liquid interface (FIG. 6B (3)). By periodically turning the laser on and off (this sequence can be readily programmed), Si/SiGe superlattice is formed on every individual nanowire (FIG. 6B (4)) in a block-by-block fashion.

The entire growth process resembles the living polymerization synthesis of block copolymer. During the growth process, the laser can be periodically turned on and off (e.g. turned on for 5 s and off for 25 s) and the cycle optionally repeated to produce the desired pattern of domains in the nanowire heterostructure. Similarly the dopant and/or the gas can be varied to alter the composition off nanowire domains.

While this method is described with reference to a silicon substrate, a gold “catalyst” and a germanium dopant, other materials can be used. Thus for example, the silicon substrate can be replaced with another material, including, but not limited to one or more materials selected from groups II, III, IV, V, or VI of the periodic table or combinations and/or alloys thereof. Similarly the “dopant” need not be limited to germanium (Ge) but can also be a material including, but not limited to one or more materials selected from groups II, III, IV, V, or VI of the periodic table or combinations and/or alloys thereof. The dopant and the reacting gas can be varied during the procedure to further vary the composition of various domains comprising the nanowire heterostructure.

The size (e.g., diameter) and/or shape of the nanowire heterostructure can be determined by the size of the gold (or other catalyst) droplet on the substrate. The use of colloidal catalysts (see, e.g., Gudiksen et al. (2001) Nature, 415: 617-620) has been show to significantly improve control of nanowire diameter and uniformity. Size of the catalyst droplet can also be varied by selective deposition of the gold (or other catalyst) droplets on the substrate (e.g. via molecular beam processes, lithographic processes, and the like). Similarly the distribution of nanowire heterostructures on the substrate can be governed by the distribution of the gold or other catalyst on that substrate.

After fabrication, of the nanowire heterostructure comprising the desired code (e.g. collection of domains having particular spectral characteristics) the nanowire heterostructure can be functionalized in a manner compatible with the system of interest.

C) Collections of Nanowire Heterostructures.

In certain embodiments, this invention pertains to the creation of collections (ensembles) of nanowire heterostructures encoding information. The nanowire heterostructure can all be of the same type, or the collection can be a heterogeneous collection. In various heterogeneous collections, the members can comprise species that differ from each other in nanowire composition and/or pattern, and/or in information encoded therein, and/or in functionalization or attached/associated binding moieties.

In certain embodiments, the nanowires are encoded so that a nanowire heterostructure code uniquely identifies each species or substantially each species (e.g. nanowire type) comprising the collection. In certain embodiments, particular species can be identified by two or more different nanowire heterostructure. In certain embodiments, the information encoded into the nanowire heterostructure identifies the nature and/or material properties of another part of the same nanowire.

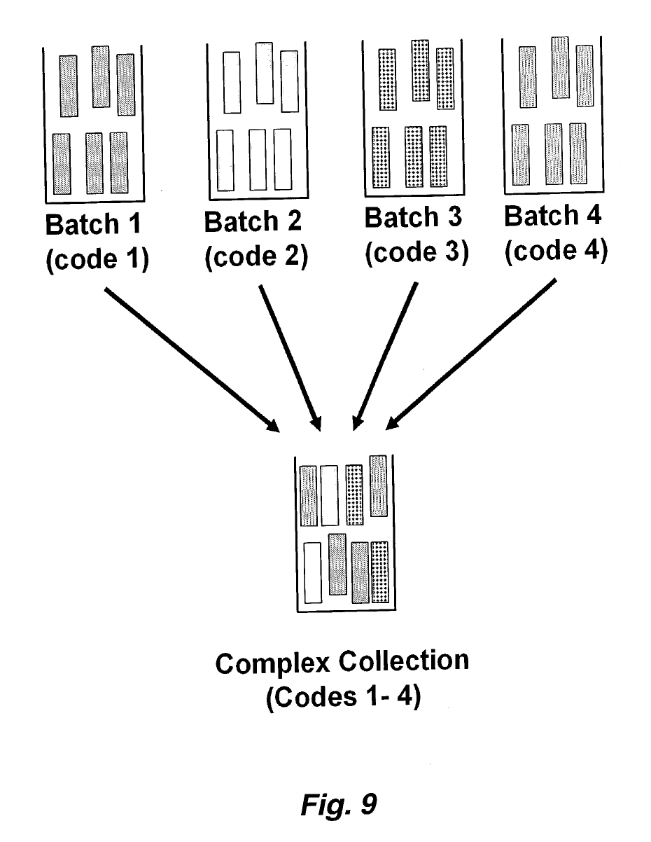

The nanowire collection can be fabricated at once, or the nanowires from each species are synthesized at different times. Thus, for example, the nanowire collection can comprise species fabricated at different times and split or combined together (see, e.g., FIG. 9).

In certain embodiments, nanowire heterostructure collections comprise at least 5 or 10, preferably at least 20 or 50, more preferably at least 100, 500, or 1000, and most preferably at least 10,000, 50,000, or 100,000 different members.

IV. Derivatizing Nanowire Heterostructures.

Nanowire heterostructures of this invention can be functionalized (derivatized) to bear particular functional groups, and/or to bear linkers having particular functional groups, and/or to bear particular binding partners (binding moieties), and the like. In certain embodiments, the nanowires can be functionalized to adhere to or react with particular substrates and/or binding partners, and/or target molecules.

In certain embodiments, the nanowires are functionalized with to bear reactive groups. Such reactive groups include, but are not limited to amino, carboxyl, hydroxyl, thiol, various halides, and the like.

In certain embodiments, the nanowires are functionalized with linkers suitable for coupling the nanowire to particular substrates, and/or to particular binding partners, and/or to particular target molecules. The linker can already be bound to the moiety it is desired to link to the nanowire heterostructure. Alternatively the linkers can simply be attached to the nanowire heterostructure and provide one or more protected or unprotected reactive groups suitable for subsequent linking/coupling steps.

In one preferred embodiment, the present invention provides a nanowire heterostructure, encoding information, linked to a linking agent, where the linking agent is capable of linking to an affinity molecule. In this context, the term “linking agent” refers to a substance (e.g. molecule) capable of linking with a nanowire heterostructure an affinity molecule (e.g. to an antibody, nucleic acid, lectin, protein, etc.).

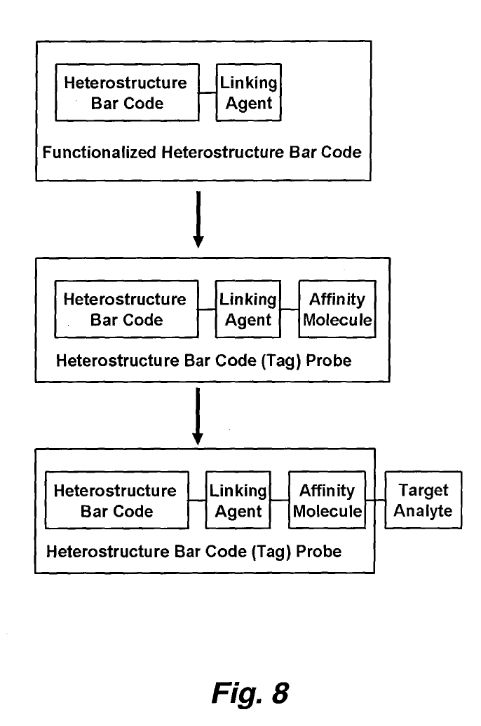

The nanowire heterostructure can then be used to link to a plurality of different linking agents that can be used to detect a plurality of different analytes (see, e.g., FIG. 8. By creating a plurality of different nanowire heterostructures, each linked to either the same or different linking agents, each linking agent then linked to a different affinity molecule such that each different affinity molecule is associated with a different nanowire heterostructure, it is possible to generate an extremely powerful multiplexed bioassay system wherein the nanowire heterostructures can be used to either label and quantify the presence of a plurality of analytes in a sample, or can be used to immobilize a single type of analyte that can then be labeled and quantified by a secondary label.

A) Attachment of Binding Partners and Other Moieties to the Nanowire.

Many methods for immobilizing binding partners (e.g. biomolecules), or other moieties, to various solid surfaces (e.g. the surface of a nanowire heterostructure) are known in the art. The desired moiety can be attached to and/or associated with the nanowire heterostructure by any a variety of interactions including, but not limited to covalent bonds, non-covalent bonds, ionic bonds, hydrophobic interactions, and the like. In this case, each of these binding forces can be considered a linking agent, as described above.

If covalent bonding between a moiety and the nanowire heterostructure is desired, the nanowire heterostructure surface will usually be functional or polyfunctional or be capable of being functionalized or polyfunctionalized. Functional groups that can be present on the surface and used for linking can include carboxylic acids, aldehydes, amino groups, cyano groups, ethylenic groups, hydroxyl groups, mercapto groups and the like. The manner of linking a wide variety of compounds to various surfaces is well known and is amply illustrated in the literature (see, e.g., , Ichiro Chibata (1978) Immobilized Enzymes, Halsted Press, New York, and Cuatrecasas, (1970) J. Biol. Chem. 245: 3059).

Information-encoding nanowire heterostructures can be functionalized by techniques known to those of skill in the art. Any functional moiety may be utilized that is capable of displacing an existing functional moiety comprising the nanowire heterostructure to provide a nanowire heterostructure with a modified functionality for a specific use.

The ability to utilize a general displacement reaction to modify selectively the surface functionality of the semiconductor nanowire heterostructures enables functionalization for specific uses. For example, because detection of biological compounds is most preferably carried out in aqueous media, a preferred embodiment of the present invention utilizes nanowire heterostructure that are solubilized in water. In the case of water-soluble nanowire heterostructure, the outer layer includes a compound having at least one linking moiety that attaches to the surface of the particle and that terminates in at least one hydrophilic moiety. The linking and hydrophilic moieties can be spanned by a hydrophobic region sufficient to prevent charge transfer across the region. The hydrophobic region also provides a “pseudo-hydrophobic” environment for the nanowire heterostructure and thereby shields it from aqueous surroundings. The hydrophilic moiety can be a polar or charged (positive or negative) group. The polarity or charge of the group provides hydrophilic interactions with water to provide stable solutions or suspensions of the nanowire heterostructures. Exemplary hydrophilic groups include polar groups such as hydroxides (—OH), amines, polyethers, such as polyethylene glycol and the like, as well as charged groups, such as carboxylates (—CO²⁻), sulfonates (SO³⁻), phosphates (—PO₄²⁻ and —PO₃²⁻), nitrates, ammonium salts (—NH⁴⁺), and the like. In certain embodiments, a water-solubilizing layer can be found at the outer surface of the overcoating layer. Methods for rendering nanowire heterostructure are similar to methods for rendering nanocrystals soluble in water and are described in International Application No: WO 00/17655.

A displacement reaction can be employed to modify the semiconductor nanowire heterostructure to improve the solubility in a particular organic solvent. For example, if it is desired to associate the nanowire heterostructure with a particular solvent or liquid, such as pyridine, the surface can be specifically modified with pyridine or pyridine-like moieties to ensure solvation.

The nanowire heterostructure surface can also be modified by displacement to render the nanowire heterostructure reactive for a particular coupling reaction. For example, displacement of moieties comprising the nanowire heterostructure with a group containing a carboxylic acid moiety enables the reaction of the modified nanowire heterostructure with amine containing moieties (commonly found on solid support units) to provide an amide linkage. Additional modifications can also be made such that the nanowire heterostructure can be associated with almost any material or molecule.

One form in which the nanowire heterostructure can be linked to an affinity molecule via a linking agent is by coating the nanowire heterostructure with a thin layer of glass, such as silica (SiO.sub.x where x=1−2), using a linking agent such as a substituted silane, e.g., 3-mercaptopropyl-trimethoxy silane to link the nanowire heterostructure to the glass. The glass-coated nanowire heterostructure can then be further treated with a linking agent, e.g., an amine such as 3-aminopropyl-trimethoxysilane, which will function to link the glass-coated nanowire heterostructure to the affinity molecule. That is, the glass-coated semiconductor nanowire heterostructure can then be linked to the affinity molecule. It is within the contemplation of this invention that the original nanowire heterostructure can also be chemically modified after it has been made in order to link effectively to the affinity molecule. A variety of references summarize the standard classes of chemistry that can be used to this end, in particular the “Handbook of Fluorescent Probes and Research Chemicals”, (6th edition) by R. P. Haugland, available from Molecular Probes, Inc., and the book “Bioconjugate Techniques”, by Greg Hermanson, available from Academic Press, New York.

When the nanowire heterostructure is coated with a thin layer of glass, the glass, by way of example, may comprise a silica glass (SiOₓ where x=1−2), having a thickness ranging from about 0.5 nm to about 10 nm, and preferably from about 0.5 nm to about 2 nm.

The nanowire heterostructure is coated with the coating of thin glass, such as silica, by first coating the nanowire heterostructure with a surfactant such as tris-octyl-phosphine oxide, and then dissolving the surfactant-coated nanowire heterostructure in a basic methanol solution of a linking agent, such as 3-mercaptopropyl-tri-methoxy silane, followed by partial hydrolysis which is followed by addition of a glass-affinity molecule linking agent such as amino-propyl trimethoxysilane which will link to the glass and serve to form a link with the affinity molecule.

When the linking agent does not involve the use of a glass coating on the nanowire heterostructure, it can comprise a number of different materials, depending upon the particular affinity molecule, which, in turn, depends upon the type of detectable material being analyzed for. It should also be noted that while an individual linking agent can be used to link to an individual nanowire heterostructure, it is also within the contemplation of the invention that more than one linking agent(s) may bond to the same nanowire heterostructure and vice versa.

A few examples of the types of linking agents that can be used to link to both the nanowire heterostructure (or to a glass coating on the nanowire heterostructure) and to the organic affinity molecule in the probe are illustrated in Table 2, below, it being understood that this is not intended to be an exhaustive list:

TABLE 2
Linkers suitable for attaching nanowire heterostructures to affinity
molecules.

| Structure | Name |
|---|---|
| 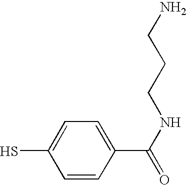 | N-(3-aminopropyl)3- mercapto-benzamide |
| 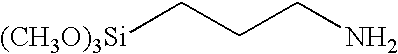 | 3-aminopropyl- trimethoxysilane |
| 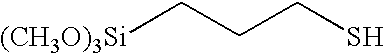 | 3-mercaptopropyl- trimethoxysilane |
| 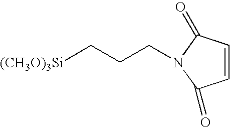 | 3-maleimidopropyl- trimethoxysilane |
| 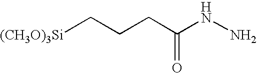 | 3-hydrazidopropyl-tri- methoxysilane |

It should be further noted that a plurality of polymerizable linking agents may be used together to form an encapsulating net or linkage around an individual nanowire heterostructure (or group of nanowire heterostructure). This is of particular interest where the particular linking agent is incapable of forming a strong bond with the nanowire heterostructure. Examples of linking agents capable of bonding together in such a manner to surround the nanocrystal with a network of linking agents include, but are not limited to: diacetylenes, acrylates, acrylamides, vinyl, styryl, and the aforementioned silicon oxide, boron oxide, phosphorus oxide, silicates, borates and phosphates.

In certain preferred embodiments, the binding partner are joined directly to the nanowire heterostructure via a reactive group or indirectly to the nanowire heterostructure via a linker (e.g. a homo- or heterobifunctional linker). Linkers suitable for joining biological binding partners are well known to those of skill in the art. For example, a protein, antibody, lectin, receptor, sugar, or nucleic acid molecule can be linked by any of a variety of linkers including, but not limited to a peptide linker, a straight or branched chain carbon chain linker, a heterocyclic carbon linker, and the like. Heterobifunctional cross linking reagents such as active esters of N-ethylmaleimide are commonly used for joining biomolecules to substrates (see, for example, Lerner et al. (1981) Proc. Nat. Acad. Sci. USA, 78: 3403-3407 and Kitagawa et al. (1976) J. Biochem., 79: 233-236, and Birch and Lennox (1995) Chapter 4 in Monoclonal Antibodies: Principles and Applications, Wiley-Liss, N.Y.).

In certain embodiment, the binding partner can be joined to the nanowire heterostructure utilizing a biotin/avidin interaction. In this embodiment, biotin or avidin, e.g. with a photolabile protecting group can be affixed to the nanowire heterostructure. Irradiation of the nanowire heterostructure in the presence of the desired moiety bearing the corresponding avidin or streptavidin, or biotin, results in coupling of the moiety to the nanowire heterostructure.

Another suitable photochemical binding approach is described by Sigrist et al. (1992) Bio/Technology, 10: 1026-1028. In this approach, interaction of ligands with organic or inorganic surfaces is mediated by photoactivatable polymers with carbene generating trifluoromethyl-aryl-diazirines that serve as linker molecules. Light activation of aryl-diazirino functions at 350 nm yields highly reactive carbenes and covalent coupling is achieved by simultaneous carbene insertion into both the ligand and the inert surface. Thus, reactive functional groups are not required on either the ligand or supporting material.

Using the teachings provided herein, other methods of coupling desired moieties to nanowire heterostructures of this invention will be apparent ton one of skill in the art.

B) Binding Partners (Affinity Molecules).

In certain embodiments, the nanowire heterostructures of this invention are affixed to one or more binding partners. A binding partner is a molecule, compound, receptor, cell, or other moiety that is capable of binding a target analyte, preferably specifically binding a target analyte. In certain embodiments, the binding partner is a biological binding partner. A biological “binding partner” or a member of a “binding pair” refers to a molecule or composition that specifically binds other molecules to form a binding complex such as antibody-antigen, lectin-carbohydrate, nucleic acid-nucleic acid, biotin-avidin, etc

The term “specifically binds”, as used herein, when referring to a biomolecule (e.g., protein, nucleic acid, antibody, etc.), refers to a binding reaction that is determinative of the presence the target analyte in a particular sample, e.g., in a heterogeneous population of proteins and other biologics. Thus, under designated conditions (e.g. immunoassay conditions in the case of an antibody, or stringent hybridization conditions in the case of a nucleic acid), the particular binding partner binds to its target (e.g. a protein or nucleic acid) and does not bind in a significant amount to other molecules in the sample.

The binding partner(s) used in this invention are selected based upon the targets that are to be identified/quantified. Thus, for example, where the target is a nucleic acid the binding partner is preferably a nucleic acid or a nucleic acid binding protein, or an antibody that specifically binds to the target nucleic acid. Where the target is a protein, the binding partner is preferably a receptor, a ligand, or an antibody that specifically binds that protein. Where the target is a sugar or glycoprotein, the binding partner is preferably a lectin, and so forth.

Suitable binding partners (capture agents) include, but are not limited to nucleic acids, proteins, receptor binding proteins, nucleic acid binding proteins, lectins, sugars, glycoproteins, antibodies, lipids, and the like. Methods of synthesizing or isolating such binding partners are well known to those of skill in the art and the preparation of several binding partners is described as well below.

1) Preparation of Binding Partners (Capture Agents).

a) Nucleic Acids.

Nucleic acids for use as binding partners in this invention can be produced or isolated according to any of a number of methods well known to those of skill in the art. In one embodiment, the nucleic acid can be an isolated naturally occurring nucleic acid (e.g., genomic DNA, cDNA, mRNA, etc.). Methods of isolating naturally occurring nucleic acids are well known to those of skill in the art (see, e.g., Sambrook et al. (1989) Molecular Cloning—A Laboratory Manual (2nd Ed.), Vol. 1-3, Cold Spring Harbor Laboratory, Cold Spring Harbor, N.Y.).

In certain preferred embodiments, the nucleic acid is created de novo, e.g. through chemical synthesis. Nucleic acids (e.g., oligonucleotides) can be chemically synthesized according to a number of methods, e.g. according to the solid phase phosphoramidite triester method described by Beaucage and Caruthers (1981), Tetrahedron Letts., 22(20): 1859-1862, e.g., using an automated synthesizer, as described in Needham-VanDevanter et al. (1984) Nucleic Acids Res., 12: 6159-6168. Purification of oligonucleotides, where necessary, is typically performed by either native acrylamide gel electrophoresis or by anion-exchange HPLC as described in Pearson and Regnier (1983) J. Chrom. 255: 137-149. The sequence of the synthetic oligonucleotides can be verified using the chemical degradation method of Maxam and Gilbert (1980) in Grossman and Moldave (eds.) Academic Press, New York, Meth. Enzymol. 65: 499-560.

b) Antibodies/antibody Fragments.

Antibodies or antibody fragments for use as binding partners (capture agents) can be produces by a number of methods well known to those of skill in the art (see, e.g., Harlow & Lane (1988) Antibodies: A Laboratory Manual, Cold Spring Harbor Laboratory, and Asai (1993) Methods in Cell Biology Vol. 37. Antibodies in Cell Biology, Academic Press, Inc. N.Y.). In one approach, the antibodies are produced by immunizing an animal (e.g. a rabbit) with an immunogen containing the epitope it is desired to recognize/capture. A number of immunogens can be used to produce specifically reactive antibodies. Recombinant protein is one preferred immunogen for the production of monoclonal or polyclonal antibodies. Naturally occurring protein can also be used either in pure or impure form. Synthetic peptides can be used as well and can be made using standard peptide synthesis chemistry (see, e.g., Barany and Merrifield, Solid-Phase Peptide Synthesis; pp. 3-284 in The Peptides: Analysis, Synthesis, Biology. Vol. 2: Special Methods in Peptide Synthesis, Part A., Merrifield et al. (1963) J. Am. Chem. Soc., 85: 2149-2156, and Stewart et al. (1984) Solid Phase Peptide Synthesis, 2nd ed. Pierce Chem. Co., Rockford, Ill.)

Methods of production of polyclonal antibodies are known to those of skill in the art. In brief, an immunogen, preferably a purified cytoskeletal component, is mixed with an adjuvant and animals are immunized. The animal's immune response to the immunogen preparation is monitored by taking test bleeds and determining the titer of reactivity to the cytoskeletal components and test compositions. When appropriately high titers of antibody to the immunogen are obtained, blood is collected from the animal and antisera are prepared. Further fractionation of the antisera to enrich for antibodies reactive to the cytoskeletal component can be done if desired. (See Harlow and Lane, supra).

Monoclonal antibodies can be obtained by various techniques familiar to those skilled in the art. Briefly, spleen cells from an animal immunized with a desired antigen are immortalized, commonly by fusion with a myeloma cell (See, Kohler and Milstein (1976) Eur. J. Immunol. 6: 511-519). Alternative methods of immortalization include transformation with Epstein Barr Virus, oncogenes, or retroviruses, or other methods well known in the art. Colonies arising from single immortalized cells are screened for production of antibodies of the desired specificity and affinity for the antigen, and yield of the monoclonal antibodies produced by such cells may be enhanced by various techniques, including injection into the peritoneal cavity of a vertebrate host. Alternatively, one may isolate DNA sequences which encode a monoclonal antibody or a binding fragment thereof by screening a DNA library from human B cells according to the general protocol outlined by Huse et al. (1989) Science, 246:1275-1281.

Antibody fragments, e.g. single chain antibodies (scFv or others), can also be produced/selected using phage display technology. The ability to express antibody fragments on the surface of viruses that infect bacteria (bacteriophage or phage) makes it possible to isolate a single binding antibody fragment from a library of greater than 10¹⁰ nonbinding clones. To express antibody fragments on the surface of phage (phage display), an antibody fragment gene is inserted into the gene encoding a phage surface protein (pIII) and the antibody fragment-pIII fusion protein is displayed on the phage surface (McCafferty et al. (1990) Nature, 348: 552-554; Hoogenboom et al. (1991) Nucleic Acids Res. 19: 4133-4137).

Since the antibody fragments on the surface of the phage are functional, phage bearing antigen binding antibody fragments can be separated from non-binding phage by antigen affinity chromatography (McCafferty et al. (1990) Nature, 348: 552-554). Depending on the affinity of the antibody fragment, enrichment factors of 20 fold-1,000,000 fold are obtained for a single round of affinity selection. By infecting bacteria with the eluted phage, however, more phage can be grown and subjected to another round of selection. In this way, an enrichment of 1000 fold in one round can become 1,000,000 fold in two rounds of selection (McCafferty et al. (1990) Nature, 348: 552-554). Thus even when enrichments are low (Marks et al. (1991) J. Mol. Biol. 222: 581-597), multiple rounds of affinity selection can lead to the isolation of rare phage. Since selection of the phage antibody library on antigen results in enrichment, the majority of clones bind antigen after as few as three to four rounds of selection. Thus only a relatively small number of clones (several hundred) need to be analyzed for binding to antigen.

Human antibodies can be produced without prior immunization by displaying very large and diverse V-gene repertoires on phage (Marks et al. (1991) J. Mol. Biol. 222: 581-597). In one embodiment natural V_{H} and V_{L} repertoires present in human peripheral blood lymphocytes are were isolated from unimmunized donors by PCR. The V-gene repertoires were spliced together at random using PCR to create a scFv gene repertoire which is was cloned into a phage vector to create a library of 30 million phage antibodies (Id.). From this single “naive” phage antibody library, binding antibody fragments have been isolated against more than 17 different antigens, including haptens, polysaccharides and proteins (Marks et al. (1991) J. Mol. Biol. 222: 581-597; Marks et al. (1993). Bio/Technology. 10: 779-783; Griffiths et al. (1993) EMBO J. 12: 725-734; Clackson et al. (1991) Nature. 352: 624-628). Antibodies have been produced against self proteins, including human thyroglobulin, immunoglobulin, tumor necrosis factor and CEA (Griffiths et al. (1993) EMBO J. 12: 725-734). It is also possible to isolate antibodies against cell surface antigens by selecting directly on intact cells. The antibody fragments are highly specific for the antigen used for selection and have affinities in the 1:M to 100 nM range (Marks et al. (1991) J. Mol. Biol. 222: 581-597; Griffiths et al. (1993) EMBO J. 12: 725-734). Larger phage antibody libraries result in the isolation of more antibodies of higher binding affinity to a greater proportion of antigens.

c) Binding Proteins.

In certain embodiments, the nanowire heterostructure is attached to a binding protein. Suitable binding proteins include, but are not limited to receptors (e.g. cell surface receptors), receptor ligands, cytokines, transcription factors and other nucleic acid binding proteins, growth factors, etc.

The protein can be isolated from natural sources, mutagenized from isolated proteins or synthesized de novo. Means of isolating naturally occurring proteins are well known to those of skill in the art. Such methods include but are not limited to well known protein purification methods including ammonium sulfate precipitation, affinity columns, column chromatography, gel electrophoresis and the like (see, generally, R. Scopes, (1982) Protein Purification, Springer-Verlag, N.Y.; Deutscher (1990) Methods in Enzymology Vol. 182: Guide to Protein Purification, Academic Press, Inc. N.Y.).

Where the protein binds a target reversibly, affinity columns bearing the target can be used to affinity purify the protein. Alternatively the protein can be recombinantly expressed with a HIS-Tag and purified using Ni2+/NTA chromatography.

In another embodiment, the protein can be chemically synthesized using standard chemical peptide synthesis techniques. Where the desired subsequences are relatively short the molecule may be synthesized as a single contiguous polypeptide. Where larger molecules are desired, subsequences can be synthesized separately (in one or more units) and then fused by condensation of the amino terminus of one molecule with the carboxyl terminus of the other molecule thereby forming a peptide bond. This is typically accomplished using the same chemistry (e.g., Fmoc, Tboc) used to couple single amino acids in commercial peptide synthesizers.

Solid phase synthesis in which the C-terminal amino acid of the sequence is attached to an insoluble support followed by sequential addition of the remaining amino acids in the sequence is the preferred method for the chemical synthesis of the polypeptides of this invention. Techniques for solid phase synthesis are described by Barany and Merrifield (1962) Solid-Phase Peptide Synthesis; pp. 3-284 in The Peptides: Analysis, Synthesis, Biology. Vol. 2: Special Methods in Peptide Synthesis, Part A., Merrifield et al. (1963) J. Am. Chem. Soc., 85: 2149-2156, and Stewart et al. (1984) Solid Phase Peptide Synthesis, 2nd ed. Pierce Chem. Co., Rockford, Ill.

In certain embodiment, the binding protein can also be synthesized using recombinant DNA methodology. Generally this involves creating a DNA sequence that encodes the binding protein, placing the DNA in an expression cassette under the control of a particular promoter, expressing the protein in a host, isolating the expressed protein and, if required, renaturing the protein.

DNA encoding binding proteins or subsequences of this invention can be prepared by any suitable method as described above, including, for example, cloning and restriction of appropriate sequences or direct chemical synthesis by methods such as the phosphotriester method of Narang et al. (1979) Meth. Enzymol. 68: 90-99; the phosphodiester method of Brown et al. (1979) Meth. Enzymol. 68: 109-151; the diethylphosphoramidite method of Beaucage et al. (1981) Tetra. Lett., 22: 1859-1862; and the solid support method of U.S. Pat. No. 4,458,066.

The nucleic acid sequences encoding the desired binding protein(s) can be expressed in a variety of host cells, including E. coli, other bacterial hosts, yeast, and various higher eukaryotic cells such as the COS, CHO and HeLa cells lines and myeloma cell lines. The recombinant protein gene will be operably linked to appropriate expression control sequences for each host. For E. coli this includes a promoter such as the T7, trp, or lambda promoters, a ribosome binding site and preferably a transcription termination signal. For eukaryotic cells, the control sequences will include a promoter and preferably an enhancer derived from immunoglobulin genes, SV40, cytomegalovirus, etc., and a polyadenylation sequence, and may include splice donor and acceptor sequences.

The plasmids can be transferred into the chosen host cell by well-known methods such as calcium chloride transformation for E. coli and calcium phosphate treatment or electroporation for mammalian cells. Cells transformed by the plasmids can be selected by resistance to antibiotics conferred by genes contained on the plasmids, such as the amp, gpt, neo and hyg genes.

Once expressed, the recombinant binding proteins can be purified according to standard procedures of the art as described above.

d) Sugars and Carbohydrates.

Other binding partners include sugars and carbohydrates. Sugars and carbohydrates can be isolated from natural sources, enzymatically synthesized or chemically synthesized. A route to production of specific oligosaccharide structures is through the use of the enzymes which make them in vivo; the glycosyltransferases. Such enzymes can be used as regio- and stereoselective catalysts for the in vitro synthesis of oligosaccharides (Ichikawa et al. (1992) Anal. Biochem. 202: 215-238). Sialyltransferase can be used in combination with additional glycosyltransferases. For example, one can use a combination of sialyltransferase and galactosyltransferases. A number of methods of using glycosyltransferases to synthesize desired oligosaccharide structures are known. Exemplary methods are described, for instance, WO 96/32491, Ito et al. (1993) Pure Appl. Chem. 65:753, and U.S. Pat. Nos. 5,352,670, 5,374,541, and 5,545,553. The enzymes and substrates can be combined in an initial reaction mixture, or alternatively, the enzymes and reagents for a second glycosyltransferase cycle can be added to the reaction medium once the first glycosyltransferase cycle has neared completion. By conducting two glycosyltransferase cycles in sequence in a single vessel, overall yields are improved over procedures in which an intermediate species is isolated.

Methods of chemical synthesis are described by Zhang et al. (1999) J. Am. Chem. Soc., 121(4): 734-753. Briefly, in this approach, a set of sugar-based building blocks is created with each block preloaded with different protecting groups. The building blocks are ranked by reactivity of each protecting group. A computer program then determines exactly which building blocks must be added to the reaction so that the sequences of reactions from fastest to slowest produces the desired compound.

V. Uses of Nanowire Heterostuctures in Tagging, Tracking, and/or Information Transmission.

The nanowire heterostructures of this invention are useful in a wide variety of applications involving tagging tracking and/or information transmission. Because the nanowire heterostructures of this invention are extremely small (typically <50 μm in length and <200 nm in diameter they can be readily incorporated into or affixed to various compositions, animals, people, or articles of manufacture and yet remain essentially undetected. When desired, e.g. when the person, animal, composition, article of manufacture is later “recovered” the nanowire heterostructure can be detected and decoded to identify information including, but not limited to point of origin, batch or production lot, manufacturer, and the like. In this manner, nanowire heterostructure can be used to distinguish counterfeit from real currency, to identify manufacturer and/or distributor(s) of various drugs or compositions or detect the unauthorized trafficking or distribution of such compositions or articles of manufacture.

In addition, the nanowire heterostructure of this invention are readily transferred upon contact, e.g. contact with compositions or currency labeled/tagged with such nanowire heterostructures. Moreover, because of their small size and the ability to create structures that emit in the IR or UV, the nanowire heterostructures are not readily detected with the naked eye. The nanowire heterostructures of this invention can therefore be used to identify persons, conveyances, or objects that come into contact with compositions, or articles of manufacture so labeled.

Thus, in certain embodiments, the nanowire heterostructures of this invention are used to tag or track compositions such as pharmaceuticals, elicit drugs, chemical toxins, bioweapons, explosives and the like, articles of manufacture such as currency, or weapons, animals and plants (e.g. transgenic animals or plants), and, in certain embodiments people (e.g. for criminal detection and/or forensic applications).

The nanowire heterostructures of this invention can also be used to identify and/or track the source of black market or gray market goods.

Because of the high density of information storage available, the nanowire heterostructures of this invention are also readily used to transmit/transport information. Essentially any information (e.g. code keys) and/or message(s) can be encoded into one or more nanowire heterostructures. The nanowire heterostructures are then transported to a new location where they are decoded to provide the desired information and/or message. Because of the difficulties of detection such nanowire heterostructure coded information is difficult to locate and/or intercept. Such codes are also very difficult to forge, making for effective security inks.

VI. Uses of Nanowire Heterostructures in Combinatorial Chemistry.

The nanowire heterostructure of this invention also find considerable use in combinatorial chemistry. In combinatorial syntheses, classes of structurally related compounds, or libraries, are typically constructed on solid supports. Each individual member of the library (e.g., each unique chemical structure) can be present in multiple copies on each of a plurality of solid supports. The present invention provides a process of coding individual members of a combinatorial chemical library synthesized on a plurality of solid supports, which process includes the step of covalently attaching to one or more of the solid supports a nanowire heterostructure of this-invention coding an identifier that provides information regarding the identity of that member of the library.

A combinatorial library is a collection of chemical entities. A combinatorial library can be prepared using various strategies. In one strategy the library is prepared by the solid phase organic synthesis of discrete compounds on individual solid supports such as beads. The large number of compounds generated in a library is obtained by a mix and split strategy common to combinatorial chemistry. The chemistry to prepare the library can consist of attachment of a suitably protected core with several sites of diversity. At each step of the mix and split strategy, a protecting group is removed and diversomers (diverse reactants that have functionality for chemical attachment) are added.

In a second strategy, the library is made by the sequential addition of each diversiomer to the expanding chemical core derived from previous diversomers such as solid phase peptide or oligonucleotide synthesis.

In one illustrative embodiment of the mix and split method a pool of solid supports derivatized with appropriate sites for library synthesis is split into as many subpools as necessary and each subpool is reacted with a different reagent. The subpools are then mixed together and split again, thus insuring a statistical distribution of each derivatized bead in each subpool. The second step of the synthesis is then carried out, and each subpool is reacted with a different reagent. The pools are mixed and split, and another synthetic step is performed. Where three reagents are used at each of the three steps, a total of 3³=27 compounds are prepared by carrying out only 3×3=9 reactions, plus two mix and split steps.

In a more general case, if n reagents are used at each step, and m steps are carried out, nm compounds are synthesized by carrying out n×m reactions. Each solid support is derivatized with only one compound. The amount of compound on one solid support depends on the size of the solid support and can be on the order of 10 picomoles to 1 nanomole. Because of the large number of compounds that can be generated and the small amounts of each compound, compound identification after release from the support using standard analysis methods can be difficult or impossible.

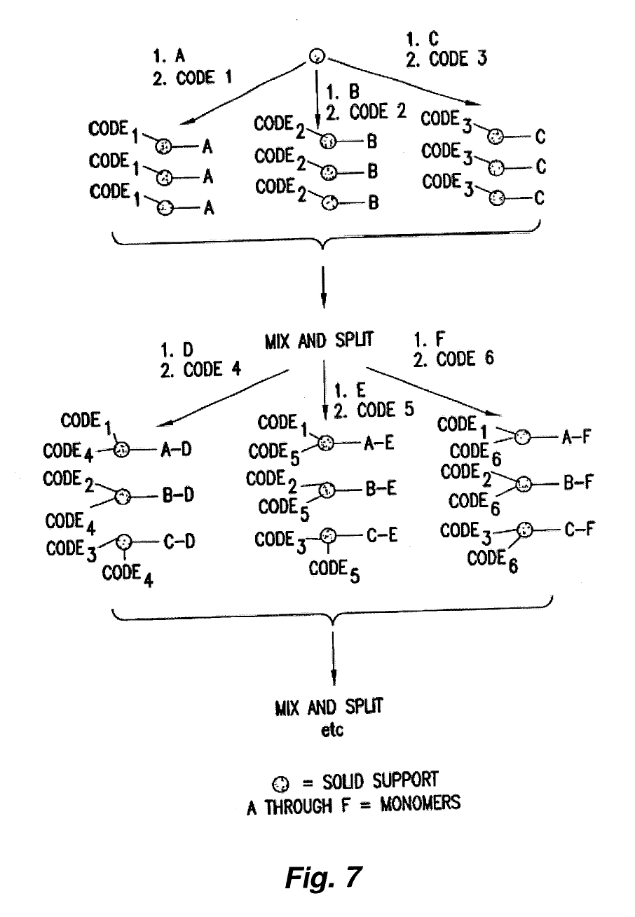

The use of a coding process of the present invention in conjunction with a mix and split strategy is shown schematically in FIG. 7. At each library chemical step and for each subpool of the library, a set of one or several coding nanowire heterostructures that bear a code unique to the synthetic step and the reactants used in that step, are covalently attached to the solid support. Reading the nanowire heterostructure after library synthesis on a particular solid support provides the chemical history of that specific support, and therefore the structure of the particular compound present on that solid support.

In one embodiment, the solid support (e.g., bead) is configured such that there are two sites of incorporation. A first site allows for incorporation of the particular library member via a suitable linker. A second site allows for incorporation of the nanowire heterostructure. By way of example, a nanowire heterostructure is chemically bound to the epsilon nitrogen of an alpha-protected lysine (Lys), ornithine (Orn) or Dap. Each chemical step is coded by the covalent attachment of an alpha protected Lys, Orn or Dap containing the nanowire heterostructure(s) to the bead. As each step of the library synthesis proceeds, the alpha protecting group of the Lys, Orn or Dap is removed and then another alpha protected Lys, Orn or Dap with another distinctive nanowire heterostructure tag is attached. In this manner, multiple reactions can be tagged.

The alpha protecting group can be a Fmoc, Bpoc, alloc, or another common protecting group whose cleavage is compatible with and orthogonal to the linker and library used. The nanowire heterostructure signature of the bead can be read either before or after cleavage and, based codes detected, the reaction history of the bead can be ascertained.

Combinatorial library synthesis methods are discussed in detail in U.S. Pat. No. 6,355,490.

VII. Uses of Nanowire Heterostructures in Assembling/fabricating Devices.

In certain embodiments, the information-encoded nanowire heterostructures of this invention are used in the fabrication of various devices (e.g. electronic circuits, sensors, and the like). The methods involve providing a plurality of elements (e.g. junctions, nanowires, gates, etc.) coupled to or comprising a nanowire heterostructure as described herein. The nanowire heterostructure encodes the identity of the element. Thus, for example, in assembling a sensor for detecting a plurality of analytes, a collection of functionalized nanowire heterostructures comprising specific binding moieties coupled to the nanowire heterostructures are provided where each specific biding moiety is associated with a particular coded nanowire heterostructure such that the code indicates the identity of the binding moiety.

The components can then be distributed on a surface, e.g. a substrate, a collection of electrodes, etc. The distribution does not need to be predetermined. After the components are coupled to the surface (e.g. through a surface active chemistry), the location of each component type is determined by reading out the code of the associated nanowire heterostructure. The location and identify of each type of element can then be placed in a convenient lookup table. The lookup table can be a printed table and/or an electronic table. The lookup table can be incorporated into the device thus fabricated and automatically accessed by an instrument used to operate and/or read the device.

VIII. Uses of Nanowire Heterostructures in Assays.

In one embodiment, this invention contemplates the use of information-encoding nanowire heterostructures of this invention associated with one or more specific-binding molecule(s) or affinity molecules to detect the presence and/or amounts of biological and chemical compounds, and/or to detect interactions in biological systems, and/or to detect biological processes, and/or to detect alterations in biological processes, and/or to detect alterations in the structure of biological compounds. Without limitation, nanowire heterostructure conjugates can comprise any molecule or molecular complex, linked to a nanowire heterostructure of this invention, that can interact with a target analyte (e.g. a biological target molecule), to detect biological processes, or reactions, and/or to alter biological molecules or processes. Preferably, the molecules or molecular complexes or conjugates physically interact with the target analyte(s). Preferably, the interactions are specific. Such interactions include, but are not limited to, covalent, noncovalent, hydrophobic, hydrophilic, electrostatic, van der Waals, or magnetic interactions.

A) Sample Preparation.

Virtually any sample can be analyzed using the devices and methods of this invention. Such samples include, but are not limited to body fluids or tissues, water, food, blood, serum, plasma, urine, feces, tissue, saliva, oils, organic solvents, earth, water, air, or food products. In certain embodiments, the sample is a biological sample. The term “biological sample”, as used herein, refers to a sample obtained from an organism or from components (e.g., cells) of an organism. The sample may be of any biological tissue or fluid. Frequently the sample will be a “clinical sample” which is a sample derived from a patient. Such samples include, but are not limited to, sputum, cerebrospinal fluid, blood, blood fractions (e.g. serum, plasma), blood cells (e.g., white cells), tissue or fine needle biopsy samples, urine, peritoneal fluid, and pleural fluid, or cells therefrom. Biological samples can also include sections of tissues such as frozen sections taken for histological purposes.

The samples, (e.g. serum, soil, etc.) can be analyzed directly or they can be subject to some preparation prior to use in the assays of this invention. Such preparation can include, but is not limited to, suspension/dilution of the sample in water or an appropriate buffer or removal of cellular debris, e.g. by centrifugation, or selection of particular fractions of the sample before analysis, and the like. The term “sample” as used herein is intended to include such “processed” samples.

B) ELISA and Related Assays.

The analyte(s) of interest can be detected using standard assay formats (e.g. standard immunoassay formats) such as competition, direct reaction, or sandwich type assays. Such assays include, but are not limited to, ELISA-like assays and biotin/avidin type assays. The reactions include the nanowire heterostructures in order to detect the formation of a complex between the binding partner (e.g. antibody) and target analyte(s).

In certain preferred embodiments, the assays involve direct “probe” assays where a specific binding moiety attached to a nanowire heterostructure label of this invention contacts the target analyte. Association of the target analyte with the labeled binding moiety indicates the presence and/or amount of target analyte present in the sample.

Detection of the target analyte is facilitated by separating analyte-bound label from free nanowire heterostructure label. This is readily accomplished by immobilizing the target analyte, e.g. on a solid support, contacting the target analyte with the labeled binding moiety, to form an immobilized analyte/binding moiety complex and then separating the complex from the unbound nanowire heterostructure labeled binding moieties (e.g. by removing the substrate from the solution, and/or by washing the sample away from the substrate.

Solid supports which can be used in the methods herein include, but are note limited to, substrates such as nitrocellulose (e.g., in membrane or microtiter well form); polyvinylchloride (e.g., sheets or microtiter wells); polystyrene latex (e.g., beads or microtiter plates); polyvinylidine fluoride; diazotized paper; nylon membranes; activated beads, magnetically responsive beads, and the like.

The target analyte(s) can be immobilized by adsorption to the substreate or the analyte can be specifically or non-specifically bound by one or more binding moieties attached to the solid support.

Sometimes, immobilization to the solid support can be enhanced, in the case of protein or antibody binding moieties, by first coupling the antigen or antibody to a protein with better solid phase-binding properties. Suitable coupling proteins include, but are not limited to, macromolecules such as serum albumins including bovine serum albumin (BSA), keyhole limpet hemocyanin, immunoglobulin molecules, thyroglobulin, ovalbumin, and other proteins well known to those skilled in the art. Other reagents that can be used to bind molecules to the support include polysaccharides, polylactic acids, polyglycolic acids, polymeric amino acids, amino acid copolymers, and the like. Such molecules and methods of coupling these molecules to antigens, are well known to those of ordinary skill in the art (see, e.g., Brinkley (1992) Bioconjugate Chem. 3: 2-13; Hashida et al. (1984) J. Appl. Biochem. 6: 56-63; and Anjaneyulu and Staros (1987) Intermnational J. of Peptide and Protein Res. 30:117-124).

In certain embodiments, the analyte is first bound to a nanowire heterostructure-labeled binding moiety and then immobilized to the solid surface, while in other embodiments, the analyte is first immobilized on the solid support and then contacted with the nanowire heterostructure labeled binding moiety. In certain other embodiments analyte immobilization and binding by the nanowire heterostructure labeled binding moiety occurs simultaneously.

The immobilized analyte need not be directly contacted with a nanowire heterostructure labeled binding moiety. In certain embodiments, the immobilized analyte is contacted with a second binding moiety, e.g. an antibody, a lectin, a nucleic acid, that specifically binds the analyte and the second binding moiety is then contacted/bound by a third moiety that is labeled with the nanowire heterostructure label.

In one particularly preferred embodiment, a multi-well plate (e.g. a microtiter plate) has wells coated with various selected antigen. A sample containing or suspected of containing antibodies to the antigen is then added to the coated wells. After a period of incubation sufficient to allow antibody binding to the immobilized antigen, the plate(s) can be washed to remove unbound moieties and a detectably labeled (labeled with a nanowire heterostructure) secondary binding molecule is added. The secondary binding molecule is allowed to react with any captured sample antibodies, the plate washed and the presence of the secondary binding molecule detected as described herein.

Thus, in one particular embodiment, the presence of bound antibody ligands from a biological sample can be readily detected using a secondary binder comprising an antibody directed against the antibody ligands, conjugated to a nanowire heterostructure. A number of immunoglobulin (Ig) molecules or other binding moieties (e.g. lectins, carbohydrates, nucleic acids, etc.) are known in the art that can be readily conjugated to nanowire heterostructures as described herein.

Assays can also be conducted in solution, such that the antigens and antibodies specific for those proteins form complexes under precipitating conditions. In one particular embodiment, antigens can be attached to a solid phase particle (e.g., an agarose bead or the like) using coupling techniques known in the art, such as by direct chemical or indirect coupling. The antigen-coated particle is then contacted under suitable binding conditions with a biological sample suspected of containing antibodies for the antigen. Cross-linking between bound antibodies causes the formation of particle-antigen-antibody complex aggregates that can be precipitated and separated from the sample using washing and/or centrifugation. The reaction mixture can be analyzed to determine the presence or absence of antibody-antigen complexes using any of a number of standard methods, such as those immunodiagnostic methods described above.

In yet a further embodiment, an affinity matrix can be provided, wherein a polyclonal population of antibodies from a biological sample suspected of containing a particular antigen is immobilized to a substrate. In this regard, an initial affinity purification of the sample can be carried out using immobilized antigens. The resultant sample preparation will thus only contain specific antibodies, avoiding potential nonspecific binding properties in the affinity support. A number of methods of immobilizing immunoglobulins (either intact or in specific fragments) at high yield and good retention of antigen binding activity are known in the art. Not being limited by any particular method, immobilized protein A or protein G can be used to immobilize immunoglobulins.

Accordingly, once the immunoglobulin molecules have been immobilized to provide an immunoaffinity matrix, nanowire heterostructure-labeled proteins are contacted with the bound antibodies under suitable binding conditions. After any nonspecifically bound antigen has been washed from the immunoaffinity support, the presence of bound antigen can be determined by assaying for label using methods described above.

Additionally, antibodies raised to particular antigens, rather than the antigens themselves, can be used in the above-described assays in order to detect the presence of a protein of interest in a given sample. These assays are performed essentially as described above and are well known to those of skill in the art.

In yet further embodiments, nanowire heterostructure-binding moiety conjugates can be used to probe fixed tissue samples or fixed cell populations for specific markers. In this embodiment, prepared cells or tissue are incubated with a binding moiety that is conjugated to a nanowire heterostructure. Nanowire heterostructures allow stable, multicolor detection of markers in both cell and tissue samples.

Nanowire heterostructure-conjugates allow specific, sensitive, photostable detection of antigens in staining procedures.

In preferred embodiments any of the foregoing assays can be run in a highly parallel (multiplexed) format for the simultaneous detection and/or quantification of a plurality of analytes. The nanowire heterostructures of this invention provide a plurality of readily distinguished labels. By associating each species of nanowire heterostructure label with a particular species of biding moiety, the identity and/or quantity of each analyte of interest can be discriminated and specifically detected.

B) Immobilized Label Assays.

In another embodiment, this invention provides for “immobilized label” assays. In these assays, an appropriately functionalized nanowire heterostructure (e.g. a nanowire heterostructure linked to (e.g., conjugated to) a specific binding moiety (e.g. antibody, nucleic acid, lectin, carbohydrate, etc.) is immobilized on a solid support. The functionalized nanowire heterostructure thereby forms a detection element. The binding element is contacted with a sample under conditions that permit binding of the target analyte(s) by the binding moiety if such analytes are present in the sample. Binding of the analyte to the detection element is then detected and the nanowire heterostructure is read/decoded to indicate the identity of the bound analyte.

In one embodiment, the nanowire heterostructure linked to a specific binding moiety is contacted with the sample prior to being immobilized on a solid support. In this embodiment, the nanowire heterostructures interact with the sample under solution-phase conditions, enhancing mixing efficiency and therefore binding efficiency of the assay. After a predetermined amount of time, the nanowire heterostructures are removed from the solution and detected. In a different particularly preferred embodiment, the assays on the nanowire heterostructure detection element can be detected without the step of immobilizing the nanowire heterostructure on a solid support. Instead, they can be analysed in solution, either before or after they are separated from the sample solution, using techniques such as flow-cytometry or confocal microscopy. In this embodiment, it is often unnecessary to purify the detection elements away from the rest of the sample solution due to the substantially higher concentration of specific analytes and labels in proximity to each detection element (i.e. because they are specifically bound to the surface of the detection element).

This format is particularly well suited to lab-on-a-chip applications, and to massively parallel high throughput screening. A plurality of binding elements (e.g. at least about 5 or 10, preferably at least about 20, 50, or 100, more preferably at least about 500, or 1000 or 10,000) can be provided attached to a substrate in a haphazard or random manner, or suspended in solution. There is no need to pre-encode the substrate. Readout of the nanowire heterostructure associated with each binding element indicates the identity of that element. A lookup table relating binding element position to binding element specificity (e.g. target analyte) or binding element “code” to binding element specificity can be generated prior to, during, or after running the assay.

Association of the bound analyte(s) with a particular binding element is readily determined. For example, the bound analytes can be contacted with labeled binding moieties specific for each analyte, or with labeled binding moieties that generally bind all of the target analytes. Where a target analyte is immobilized to the binding element, the target analyte will bind the labeled binding moieties. Detection of the label in association with the binding element(s) indicates the presence or quantity of the analyte and, as indicated above, decoding of the nanowire heterostructure indicates the identity of the analyte.

C) Nanowire Heterostructures for Detection Reagents in In Situ Hybridization

In another embodiment of the invention, in situ hybridization (ISH) or fluroescen tin situ hybridization (FISH) assays using a nanowire heterostructure as a detectable label are disclosed. Techniques for performing various types of ISH assays are well known in the art (see, e.g., Raap (1998) Mutation Res. 400: 287-298; Speel et al. (1998) Histochem. Cell. Biol. 110: 571-577; Nath and Johnson (1997) Biotech. Histochem. 73 :6-22; Swiger and Tucker (1996) Environ. Molec. Mutagen. 27: 245-254; Kitadai et al. (1995) Clin. Cancer Res. 1: 1095-1102; Heiskanen et al. (1995) Genomics 30: 31-36; and Heiskanen et al. (1994) BioTechniques 17:928-933). Information encoded nanowire heterostructures can be substituted for the labels normally used in each of these techniques. The advantages of nucleic acid probes labeled with nanowire heterostructure is that multiple probes directed at distinct target oligonucleotides can be used simultaneously by virtue of the fact that a plurality of populations of nanowire heterostructure can be made with characteristically different signatures, each of which, in the case of fluorescent encoding, can be excited with a single source and wavelength of light. The ability to “multiplex” assays in this manner is especially useful when the specimen to be analyzed contains a limited source of cells or tissues, e.g., rare cells, fetal cells in maternal blood, cancer cells in blood or urine samples, blastomeres, or the like. By multiplexing, multiparametric information at the single cell level may be collected (see, e.g., Patterson et al. (1998) Cytometry 31: 265-274; Borzi et al. (1996) J. Immunol. Meth. 193: 167-176; Wachtel et al. (1998) Prenat. Diagn. 18: 455-463; Bianchi (1998) J. Perinat. Med. 26: 175-185; and Munne (1998) Mol. Hum. Reprod. 4: 863-870).

Nanowire heterostructure encoding different information can be chemically linked to nucleic acid (DNA or RNA) or indirectly linked to streptavidin/biotin that binds to nucleic acid. Nanowire heterostructure bind to DNA primers or incorporate into nucleic acid by using nanowire heterostructure-linked nucleotide(s). PCR can be used to generate nucleic acid fragments for ISH probes. Nanowire heterostructure can also be chemically attached to a nucleic acid containing the sequence of interest. Alternatively, biotin molecules can be attached to oligonucleotide primers, or incorporated into nucleic acid of interest by using biotinlyated nucleotides in PCR. Nanowire heterostructures attached to streptavidin can then be linked to biotin in the nucleic acid probe. These nanowire heterostructure-ISH probes can be use for in situ hybridization for DNA (see, e.g., Dewald et al. (1993) Bone Marrow Transplantation 12: 149-154; Ward et al. (1993) Am. J. Hum. Genet. 52: 854-865; Jalal et al. (1998) Mayo Clin. Proc. 73: 132-137; Zahed et al. (1992) Prenat. Diagn. 12:483-493; Neuhaus et al. (1999) Human Pathol. 30:81-86; Buno et al. (1998) Blood 92: 2315-2321; Munne (1998) Mol. Hum. Reprod. 4: 863-870, and RNA (see e.g., Kitadai et al. (1995) Clin. Cancer Res. 1:1095-1102). The results can be analyzed, for example, under an epi fluorescence microscope. Nanowire heterostructure-FISH probe or probes for DNA and RNA together (see, e.g., Wachtel et al. (1998) Prenat. Diagn. 18: 455-463), or for RNA and surface immunophenotyping together (see, e.g., Patterson et al. (1998) Cytometry 31: 265-274; Borzi et al. (1996) J. Immunol. Meth. 193: 167-176) can be used to identify, sort, and analyze rare cells simultaneously. In the case where only short oligonucleotide nanowire heterostructure-FISH probes (forward and reverse primers) for RNA or DNA are available, sensitivity of probes can be increased through PCR/FISH or RT-PCR/FISH. This can be accomplished by incorporating a nanowire heterostructure-dNTP into the in situ PCR or RT-PCR reaction. (see, e.g., Patterson et al. (1993) Science 260:976-979; Patterson et al. (1998) Cytometry 31: 265-274).

The detection system may be a microscope, or flow cytometer, or detector capable of measuring the wavelength of light emitted from the different nanowire heterostructures.

ISH and FISH technologies are widely used in research and clinical molecular cytogenetics, pathology and immunology laboratories. Nanowire heterostructure-DNA probes can be use to detect amplification (e.g., HER2/neu, c myc genes amplification), addition (e.g., trisomy 21, 13, 18), deletion (e.g., 45.times., Turner's Syndrome), translocation (e.g., BCR/ABL in CML) of DNA in the nuclei.

Nanowire heterostructure-RNA probes can be used to localize and to monitor expression of genes (mRNA) in the cell. This is especially useful for detecting rare cells (e.g. fetal cells in maternal blood, cancer cells for monitoring disease recurrence).

Nanowire heterostructures can be conjugated to antibodies, to a protein of interest (antigen) to detect protein expression and/or sort out cells of interest. Multiple nanowire heterostructure-antibody(ies), nanowire heterostructure-nucleic acid probes for RNA and or DNA can be used to hybridize with cells in the same or sequential reaction. Cells of interest in the population (rare cells) can then be identified and analyzed for DNA (for genetic composition) or mRNA (for gene expression) simultaneously.

Specimens for ISH or FISH can include cells (alive or fixed) or nuclei in suspension or attached to microscope slides or other solid supports or paraffin embedded tissue sections containing one, or more than one specimen, or frozen tissue sections or fine needle aspirate. ISH and FISH can be performed on metaphase or interphase cells or directly onto DNA strands.

The specimen for the ISH or FISH assay is prepared using well known methods depending on the specimen type, for example: peripheral blood (Hack et al., eds., (1980), supra; Buno et al. (1998), supra; Patterson et al. (1993), supra; Patterson et al. (1998), supra; Borzi et al. (1996), supra); bone marrow (Dewald et al. (1993), supra; Hack et al., eds., (1980), supra); amniocytes (Ward et al. (1993), supra; Jalal et al. (1998), supra); CVS (Zahed et al. (1992), supra); paraffin embedded tissue sections (Kitadai et al. (1995); supra; Neuhaus et al. (1999), supra); fetal cells (Wachtel et al. (1998), supra; Bianchi (1998), supra); and blastomeres (Munne (1998), supra).

D) Nanowire Heterostructures as Detection Reagents in Signal Amplification Assays

In yet another embodiment of the invention, a method is disclosed for using nanowire heterostructure as a signal-generating label and nanowire heterostructure conjugates as the detection reagent in signal amplification assay formats. This type of signal amplification provides several advantages over currently employed methods for detecting the signal in signal-amplification assays. Among these advantages is the ability to detect multiple analytes in the same sample simultaneously with high sensitivity.

Nanowire heterostructures having different signatures are individually conjugated to distinct molecules (a “nanowire heterostructure-conjugate”) that specifically recognize an amplification complex generated in response to the presence of an analyte in a sample. A nanowire heterostructure-conjugate can be, for example, the label in 1) a DNA hybridization assay; or 2) a biotin/avidin-layered amplification assay. The detection system is a device capable of measuring and distinguishing the information encoded in the nanowire heterostructures.

E) Nanowire Heterostructure for use in Multiplexed, Single Tube Assays

In still another embodiment of the invention, an HTS assay using nanowire heterostructures as multiplexed detection reagents is provided. Nanowire heterostructure encoding a particular signature are conjugated by one of the techniques described herein or in the references cited herein, or by any technique known in the art for attaching or conjugating proteins, nucleic acids, and the like (see, e.g., Hermanson (1996) Bioconjugate Techniques (Academic Press)).

The HTS assay is performed in the presence of various concentrations of a candidate compound. The nanowire heterostructure signature is monitored as an indication of the effect of the candidate compound on the assay system. This technique is amenable to any of the conventional techniques. For example, fluorescence reading using a nanowire heterostructure-conjugated ligand or receptor to monitor binding thereof to a bead-bound receptor or ligand, respectively, can be used as a flexible format to measure the nanowire heterostructure emission associated with the beads. The measure of nanowire heterostructure emission associated with the beads can be a function of the concentration of candidate compound and, thus, of the effect of the candidate compound on the system. Alternatively, the nanowire heterostructure can play the role of the bead in the previous embodiement, with a different label (e.g. a fluorescent dye, quantum dot or even a second nanowire heterostructure) as the assay readout. In this embodiment, throughput is increased by being able to multiplex the equivalent of the bead-bound receptor). In some embodiments, nanowire heterostructures of the present invention can even be directly incorporated into polymer or glassy beads to encode those beads for assay and inventory control purposes. In addition, nanowire heterostructure can be used as a multicolor scintillant to detect the binding of a radiolabeled ligand or receptor with a nanowire heterostructure-conjugated receptor or ligand, respectively. A decrease in scintillation would be one result of inhibition by the candidate compound of the ligand-receptor pair binding.

F) Assay Formats and Optimization.

The assays described herein have immediate utility in screening for the presence or quantity of one or more target analytes. The assays of this invention can be optimized for use in particular contexts, depending, for example, on the source and/or nature of the biological sample and/or the particular test agents, and/or the analytic facilities available. Thus, for example, optimization can involve determining optimal conditions for binding assays, optimum sample processing conditions (e.g. preferred PCR conditions), hybridization conditions that maximize signal to noise, protocols that improve throughput, etc. In addition, assay formats can be selected and/or optimized according to the availability of equipment and/or reagents.

Typically assays are run under conditions that optimize binding between a biding moieties and target analyte(s). Conditions are also selected to maximize a signal to noise ratio.

In the case of nucleic acid/nucleic acid interactions, nucleic acid hybridization simply involves providing a denatured probe and target nucleic acid under conditions where the probe and its complementary target can form stable hybrid duplexes through complementary base pairing. The nucleic acids that do not form hybrid duplexes are then typically washed away leaving the hybridized nucleic acids to be detected, typically through detection of the attached nanowire heterostructure or other label. It is generally recognized that nucleic acids are denatured by increasing the temperature or decreasing the salt concentration of the buffer containing the nucleic acids, or in the addition of chemical agents, or the raising of the pH. Under low stringency conditions (e.g., low temperature and/or high salt and/or high target concentration) hybrid duplexes (e.g., DNA:DNA, RNA:RNA, or RNA:DNA) will form even where the annealed sequences are not perfectly complementary. Thus specificity of hybridization is reduced at lower stringency. Conversely, at higher stringency (e.g., higher temperature or lower salt) successful hybridization requires fewer mismatches.

One of skill in the art will appreciate that hybridization conditions can be selected to provide any degree of stringency. In a preferred embodiment, hybridization is performed at low stringency to ensure hybridization and then subsequent washes are performed at higher stringency to eliminate mismatched hybrid duplexes. Successive washes may be performed at increasingly higher stringency (e.g., down to as low as 0.25×SSPE at 37° C. to 70° C.) until a desired level of hybridization specificity is obtained. Stringency can also be increased by addition of agents such as formamide. Hybridization specificity may be evaluated by comparison of hybridization to the test probes with hybridization to the various controls that can be present.

In general, there is a tradeoff between hybridization specificity (stringency) and signal intensity. Thus, in a preferred embodiment, the wash is performed at the highest stringency that produces consistent results and that provides a signal intensity greater than approximately 10% of the background intensity. Thus, in a preferred embodiment, the hybridized array may be washed at successively higher stringency solutions and read between each wash. Analysis of the data sets thus produced will reveal a wash stringency above which the hybridization pattern is not appreciably altered and which provides adequate signal for the particular probes of interest.

In a preferred embodiment, background signal is reduced by the use of a blocking reagent (e.g., tRNA, sperm DNA, cot-1 DNA, etc.) during the hybridization to reduce non-specific binding. The use of blocking agents in hybridization is well known to those of skill in the art (see, e.g., Chapter 8 in P. Tijssen, supra.)

Methods of optimizing hybridization conditions are well known to those of skill in the art (see, e.g., Tijssen (1993) Laboratory Techniques in Biochemistry and Molecular Biology, Vol. 24: Hybridization With Nucleic Acid Probes, Elsevier, N.Y.).

Optimal conditions are also a function of the sensitivity of label (e.g., fluorescence) detection for different combinations of substrate type, fluorochrome, excitation and emission bands, spot size and the like. Low fluorescence background surfaces can be used (see, e.g., Chu (1992) Electrophoresis 13:105-114). The sensitivity for detection of spots or nanowire heterostructures on the candidate surfaces can be readily determined by, e.g., spotting a dilution series of suitably labeled DNA fragments. These spots are then imaged using conventional fluorescence microscopy. The sensitivity, linearity, and dynamic range achievable from the various combinations of label and solid surfaces (e.g., glass, fused silica, etc.) can thus be determined.

IX. Kits Comprising Encoded Nanowires.

In certain embodiments, this invention provides kits for practice of the methods described herein. In various embodiments, such kits comprise a container or containers containing one or more of the following: a nanowire heterostructure as described herein, a collection of nanowire heterostructures, a junction as described herein.

The kit can any reagents, devices/apparatus, and materials additionally used to fabricate nanowire heterostructures, to read/decode nanowire heterostructures, to assemble nanowire heterostructures and the like. Such reagents, devices and materials include, but are not limited to reagents for functionalizing nanowire heterostructures, buffers for suspending nanowire heterostructures, microfluidic devices (e.g., lab on a chip), microscopes, and the like.

In addition, the kits can optionally include instructional materials containing directions (i.e., protocols) for the synthesis and/or encoding, and/or decoding of nanowire heterostructures and/or for the practice of any of the methods of this invention. Preferred instructional materials provide protocols utilizing the kit contents encoding and/or decoding nanowire heterostructures, and/or for detecting nanowire heterostructures, and/or for functionalizing nanowire heterostructures, and/or for performing any of the assays described herein, and the like.

In certain embodiments, the instructional materials teach the use of the nanowire heterostructures in the fabrication of one or more devices, e.g. an electronic device, an optoelectronic device, a spintronic device, an optical device, etc. In certain preferred embodiments, the kits teach the use of the nanowire heterostructures in the fabrication and/or use of a sensor (e.g. a biosensor).

While the instructional materials typically comprise written or printed materials they are not limited to such. Any medium capable of storing such instructions and communicating them to an end user is contemplated by this invention. Such media include, but are not limited to electronic storage media (e.g., magnetic discs, tapes, cartridges, chips), optical media (e.g., CD ROM), and the like.

X. Systems Comprising Encoded Nanowires.

In still another embodiment, this invention contemplates systems and the use of systems for storing and/or retrieving information in one or more nanowire heterostructures. In certain embodiments, such an information storage and retrieval system comprises a nanowire heterostructure encoding information as described and a device that detects the nanowire heterostructure and/or reads and/or decodes the information stored therein. As described herein, the device can be any device that is capable of detecting the modality in which the information is stored in the nanowire heterostructure. Various suitable devices include, but are not limited to a microscope, a telescope, an optical system, an image acquisition system, a fluorometer, an emission spectrophotometer, an absorption spectrophotometer, a magnetometer, an atomic force microscope (AFM), a scanning tunneling microscope (STM), a transmission electron microscope, and a scanning electron microscope, and the like.

In certain embodiments, the system can include an excitation source for exciting a signal from the nanowire heterostructures. Depending on the nature of the nanowire heterostructure, a wide variety of excitation sources can be used. Such sources include, but are not limited to an optical source (e.g. an infra-red or near infra red source, an ultraviolet source, etc.), a laser, an incandescent or fluorescent lamp, a light emitting diode, a source of potential, a source of charge, a source of current, a radio or microwave emission, a magnetic field, an electric field, and the like.

In various embodiments, this invention contemplates devices that are in direct contact or close proximity to the nanowire heterostructure to read the encoded information (e.g. an AFT, an STM, etc.) In other embodiments, the device is one capable of remote sensing/detection and the device does not need to be in contact or even very close to the nanowire heterostructure to read the code stored therein.

In certain embodiments, the system additionally comprises a device to synthesize the nanowire heterostructure as described herein.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes and to the same extent as if each individual publication or patent application was specifically and individually indicated to be incorporated by reference.

What is claimed is:

1. A nanowire heterostructure comprising at least a first material type and a second material type wherein said first material type and said second material type delineate at least two different and distinguishable domains, wherein said domains store coded information.

2. The nanowire heterostructure of claim 1, wherein said nanowire has a substantially uniform diameter of about 200 nm or less.

3. The nanowire heterostructure of claim 1, wherein said nanowire has an aspect ration greater than about 2.

4. The nanowire heterostructure of claim 1, wherein said nanowire heterostructure encodes at least 8 bits of information.

5. The nanowire heterostructure of claim 1, wherein said information is spatially encoded by the position of said domains along said nanowire.

6. The nanowire heterostructure of claim 1, wherein said information us spatially encoded by the length of said domains along said nanowire.

7. The nanowire heterostructure of claim 1, wherein said information is spatially encoded by the length and position of said domains along said nanowire.

8. The nanowire heterostructure of claim 1, wherein said information is encoded by the optical properties of said domains.

9. The nanowire heterostructure of claim 8, wherein one or more of said domains are fluorescent.

10. The nanowire of claim 9, wherein said information is encoded in the fluorescence intensity of said domains.

11. The nanowire of claim 9, wherein said information is encoded in the peak emission wavelength of said domains.

12. The nanowire of claim 9, wherein said information is encoded in the emission spectrum of said domains.

13. The nanowire heterostructure of claim 1, wherein said information is encoded by the electrical properties of said domains.

14. The nanowire heterostructure of claim 1, wherein said information is encoded by the magnetic properties of said domains.

15. The nanowire heterostructure of claim 1, wherein said information comprises the composition of said nanowire heterostructure.

16. The nanowire heterostructure of claim 1, wherein said information comprises the identity of said nanowire heterostructure.

17. The nanowire heterostructure of claim 1, wherein said first material type and said second material type differ from each other in a property selected from the group consisting of an optical property, an electrical property, and a magnetic property.

18. The nanowire heterostructure of claim 11, wherein said optical property comprises one or more properties selected from the group consisting of a color, an absorption spectrum, an emission spectrum, an emission intensity, and a fluorescence intensity.

19. The nanowire heterostructure of claim 1, wherein said first material type is a semiconductor.

20. The nanowire heterostructure of claim 19, wherein said semiconductor is a doped semiconductor.

21. The nanowire heterostructure of claim 1, wherein said first material type is a first semiconductor and said second material type is a second semiconductor.

22. The nanowire heterostructure of claim 21, wherein said first semiconductor is a doped semiconductor and said second semiconductor is a doped semiconductor.

23. The nanowire heterostructure of claim 18, wherein said first semiconductor is an n-doped semiconductor, said second semiconductor is a p-doped semiconductor and the transition region between the first and second semiconductor is a fluorescent region.

24. The nanowire heterostructure of claim 23, wherein information is encoded in the spatial distribution of a plurality of transition regions between n-doped and p-doped semiconductors comprising said nanowire heterostructure.

25. The nanowire heterostructure of claim 1, wherein said first material type and said second material type differ in magnetic properties.

26. The nanowire heterostructure of claim 1, wherein said at least two different and distinguishable domains comprise a first domain and a second domain wherein said first domain differs in absorption or emission spectra from said second domain.

27. The nanowire heterostructure of claim 26, wherein at least one of said absorption and emission spectra of at least one of said first and second domain comprises a comprises an infrared absorption and emission spectrum.

28. The nanowire heterostructure of claim 26, wherein the nanowire is substantially invisible to the human eye.

29. The nanowire heterostructure of claim 26, wherein said emission spectrum comprises substantially only IR emission.

30. The nanowire heterostructure of claim 26, wherein said emission spectrum comprises substantially only UV emission.

31. The nanowire heterostructure of claim 26, wherein said emission spectrum comprises substantially only visible light.

32. The nanowire heterostructure of claim 26, wherein said first domain is a fluorescent domain and said second domain is a fluorescent domain.

33. The nanowire heterostructure of claim 32, wherein said first domain has an essentially monochromatic emission spectrum.

34. The nanowire heterostructure of claim 33, wherein the emission wavelength of said first domain depends on the length or diameter of the domain.

35. The nanowire heterostructure of claim 32, wherein said first domain and said second domain each have an essentially monochromatic emission spectrum.

36. The nanowire heterostructure of claim 32, wherein said first domain and said second domain are sufficiently close to each other that they form a coding region having a polychromatic emission spectrum.

37. The nanowire heterostructure of claim 32, wherein said nanowire comprises a plurality of different fluorescent domains located within a region whose length is less than the wavelength of the longest wavelength of light emitted from said domains.

38. The nanowire heterostructure of claim 32, wherein said nanowire comprises a plurality of different fluorescent domains located within a region whose length is less than the diffraction limit of the longest wavelength of light emitted by said domains.

39. The nanowire heterostructure of claim 36, wherein said nanowire heterostructure comprises a plurality of coding regions.

40. The nanowire heterostructure of claim 39, wherein said nanowire heterostructure is less than about 500 nm long.

41. The nanowire heterostructure of claim 1, wherein said nanowire has a diameter of less than about 200 nm.

42. The nanowire heterostructure of claim 1, wherein said nanowire has a substantially uniform diameter.

43. The nanowire heterostructure of claim 1, wherein said nanowire is characterized by a substantially crystalline core.

44. The nanowire heterostructure of claim 43, wherein said nanowire is characterized by a substantially monocrystalline core.

45. The nanowire heterostructure of claim 1, wherein said nanowire heterostructure is functionalized.

46. The nanowire heterostructure of claim 45, wherein said nanowire is functionalized with a functional group selected from the group consisting of a hydroxyl, an amino, a carboxyl, and a thiol.

47. The nanowire heterostructure of claim 45, wherein said nanowire is functionalized with a binding moiety selected from the group consisting of a nucleic acid, an antibody, a lectin, a receptor, a cytokine, a growth factor, a nucleic acid binding protein, a sugar, a carbohydrate, a polypeptide, a lectin, a cell, a receptor, a small organic molecule, an avidin, a streptavidin, an aptamer, an aptazyme, and a biotin.

48. The nanowire heterostructure of claim 1, wherein said nanowire heterostructure is electrically coupled to one or more electrodes.

49. The nanowire heterostructure of claim 1, wherein said nanowire heterostructure is optically coupled to one or more photonic devices.

50. The nanowire heterostructure of claim 1, wherein said nanowire heterostructure forms one or more junctions with one or more second nanowires.

51. A functionalized nanowire heterostructure comprising a nanowire heterostructure of claim 1 attached to an affinity molecule whereby said functionalized nanowire changes electrical, or optical properties upon binding of said affinity molecule to a target.

52. A collection of nanowire heterostructures, said collection comprising a plurality of nanowire heterostructures of claim 1, wherein the nanowire heterostructures comprising said collection carry substantially the same code.

53. The collection of claim 52, wherein said collection comprises at least 1000 different members.

54. The collection of claim 52, wherein the variation any one of a characteristic selected from the group consisting of a location of the domains, a length of the domains, a diameter of the domains, an optical property of the domains, an electrical property of the domains, and a magnetic property of the domains is sufficiently small to distinguish members of said collection from members of a second collection of nanowire heterostructures of claim 1 encoding different information.

55. The collection of claim 52, wherein the nanowires comprising said collection are functionalized.

56. The collection of claim 55, wherein the nanowires comprising said collection are functionalized with a binding partner.

57. The collection of claim 56, wherein the nanowires comprising said collection are functionalized with a binding partner selected from the group consisting of an antibody, a lectin, a receptor, a cytokine, a growth factor, a nucleic acid binding protein, a sugar, a carbohydrate, a polypeptide, a lectin, a cell, a receptor, a small organic molecule, an avidin, a streptavidin, an aptamer, an aptazyme, and a biotin.

58. The collection of claim 56, wherein the nanowire heterostructures comprising said collection are functionalized with a functional group selected from the group consisting of a hydroxyl, an amino, a carboxyl, a halide, and a thiol.

59. The collection of claim 52, wherein members of said collection are electrically coupled to one or more electrodes.

60. The collection of claim 52, wherein members of said collection are optically coupled to one or more photonic devices.

61. The collection of claim 52, wherein members of said collection form one or more junctions with one or more second nanowires.

62. The collection of claim 61, wherein said junction is ohmic.

63. The collection of claim 61, wherein said junction is not ohmic.

64. The collection of claim 61, wherein said junction is selected from the group consisting of pn, pnp, npn, pi, pnp, npn, pi, pin, pip, and nin.

65. The collection of claim 61, wherein the doping level of either side of said junction is substantially different.

66. The collection of claim 52, wherein the average diameter of the nanowire heterostructures comprising the collection is less than 200 nm.

67. The collection of claim 52, wherein the distribution of diameters of the nanowires comprising said collection has a coefficient of variance less than 50%.

68. The collection of claim 52, wherein the average diameter of the nanowire heterostructures comprising said collection is less than 200 nm and the distribution of diameters of the nanowires comprising said collection has a coefficient of variance less than 50%.

69. A collection of nanowire heterostructures, said collection comprising two or more species of nanowire heterostructures of claim 1, wherein each species is coded with information providing a signature unique for each species of nanowire heterostructure comprising said collection.

70. The collection of claim 69 wherein said signature allows the wires from said two or more species of nanowires to be distinguished from each other more than 50% of the time.

71. The collection of claim 69, wherein the nanowire heterostructures comprising said collection are functionalized.

72. The collection of claim 69, wherein the nanowire heterostructures comprising said collection are functionalized such that each species of coded nanowire is associated with a particular functionality.

73. The collection of any of claim 69, 71, or 72, wherein the nanowire heterostructures comprising said collection are functionalized with a binding partner.

74. The collection of claim 73, wherein the nanowire heterostructures comprising said collection are functionalized with a binding partner selected from the group consisting of a nucleic acid, an antibody, a lectin, a receptor, a cytokine, a growth factor, a nucleic acid binding protein, a sugar, a carbohydrate, a polypeptide, a lectin, a cell, a receptor, a small organic molecule, an avidin, a streptavidin, an aptamer, an aptazyme, and a biotin.

75. The collection of claim 73, wherein the nanowire heterostructures comprising said collection are functionalized with a functional group selected from the group consisting of a hydroxyl, an amino, a carboxyl, a thiol, and a halide.

76. The collection of claim 69, wherein members of said collection are electrically coupled to one or more electrodes.

77. The collection of claim 69, wherein members of said collection are optically coupled to one or more photonic devices.

78. The collection of claim 69, wherein members of said collection form one or more junctions with one or more second nanowires.

79. The collection of claim 78, wherein said junction is ohmic.

80. The collection of claim 78, wherein said junction is not ohmic.

81. The collection of claim 78, wherein said junction is selected from the group consisting of pn, pn, pnp, npn, pi, pnp, npn, pi, pin, pip, and nin.

82. The collection of claim 78, wherein said the doping level of either side of said junction is substantially different.

83. The collection of claim 69, wherein members of said collection are form a junction with one or more nanowires.

84. A junction comprising a nanowire heterostructure of claim 1 electrically or optically coupled to a second nanowire or to an electrode.

85. The junction of claim 84, wherein said junction comprises a nanowire of claim 1 electrically coupled to an electrode, wherein the electrical coupling is ohmic.

86. The junction of claim 84, wherein said junction comprises a nanowire of claim 1 optically coupled to a light source, light guide, or light detector.

87. The junction of claim 84, wherein said junction comprises a nanowire of claim 1 electrically coupled to a second nanowire.

88. The junction of claim 87, wherein the electrical coupling is via electron tunneling.

89. The junction of claim 87, wherein the electrical coupling is ohmic.

90. The junction of claim 87, wherein said electrical coupling is not ohmic.

91. The junction of claim 87, wherein said junction is selected from the group consisting of pn, pnp, npn, pi, pnp, npn, pi, pin, pip, and nin.

92. The junction of claim 87, wherein said the doping level of either side of said junction is substantially different.

93. The junction of claim 87, wherein said junction is encapsulated.

94. The junction of claim 87, wherein said junction comprises an element of a circuit.

95. A kit comprising a container containing a component selected from the group consisting of a nanowire heterostructure of claim 1, a collection of nanowire heterostructures of claim 52, a collection of nanowire heterostructures of claim 69, and a junction of claim 84.

96. The kit of claim 95, wherein said nanowire heterostructures are in a solution.

97. The kit of claim 95, further comprising instructional materials teaching the use of the nanowire heterostructure, the collection of a nanowire heterostructures, or junction in the fabrication of a device.

98. The kit of claim 97, wherein said device is a device selected from the group consisting of an electronic device, an optoelectronic device, a spintronic device, an optical device, a sensor, a biological sensor, and a chemical sensor.

99. An information storage and retrieval system, said system comprising:
a nanowire heterostructure according claim 1; and
a device that detects said nanowire heterostructure and reads the information stored therein.

100. The system of claim 99, wherein said device comprises a component selected from the group consisting of a microscope, a telescope, an optical system, an image acquisition system, a fluorometer, an emission spectrophotometer, an absorption spectrophotometer, a magnetometer, an atomic force microscope (AFM), a scanning tunneling microscope (STM), and a transition electron microscope, a transmission electron microscope, and a scanning electron microscope.

101. The system of claim 99, further comprising a device to synthesize said nanowire heterostructure.

102. The system of claim 99, further comprising an excitation source for exciting a signal from the nanowires.

103. The system of claim 101, wherein the excitation source is an optical source.

104. The system of claim 101, wherein the optical source is an IR or NIR source

105. The system of claim 101, wherein optical the source is a laser.

106. The system of claim 101, wherein the source is a lamp.

107. The system of claim 101, wherein the source is a solid state LED.

108. The system of claim 99, wherein the detection system does not need to be in contact with the nanowire heterostructure to read the code therein.

109. The method of claim 108, wherein said emission comprises substantially only an emission selected from the group consisting of an IR emission, a UV emission, and a visible emission.

110. The system of claim 92, wherein the detection system can be located more than 1 meter from the heterostructure and still read the code.

111. A nanowire heterostructure comprising a plurality of domains, wherein said domains comprise at least two different material types, wherein said domains store coded information.

112. A method of storing information, said method comprising:
encoding information into a format compatible with storage in a nanowire heterostructure of claims 1; and
preparing a nanowire heterostructure encoding said information.

113. The method of claim 112, wherein said nanowire heterostructure is prepared by a method selected from the group consisting of CVD, MOCVD, VLS, and modified VLS.

114. The method of claim 112, said method further comprising detecting said nanowire.

115. The method of claim 114, further comprising decoding said nanowire heterostructure to read the coded information.

116. The method of claim 115, wherein said decoding comprises reading an electronic signature.

117. The method of claim 115, wherein said decoding comprises reading an optical signature.

118. The method of claim 115, wherein said decoding comprises reading a magnetic signature.

119. The method of claim 115, wherein said decoding comprises determining an emission spectrum of one or more domains comprising said nanowire heterostructure.

120. The method of claim 115, wherein said decoding comprises determining an absorption spectrum of one or more domains comprising said nanowire heterostructure.

121. The method of claim 115, wherein said nanowire is decoded after said nanowire is transported to a new location.

122. A method of transporting information from a first location to a second location, said method comprising:
encoding information at a first location into a format compatible with storage in a nanowire heterostructure of claim 1;
preparing a nanowire heterostructure encoding said information;
transporting said nanowire heterostructure to said second location; and
decoding said nanowire heterostructure to read the coded information.

123. The method of claim 116, wherein said transporting comprises carrying of said nanowire by a human or a non-human animal.

124. The method of claim 116, wherein said transporting comprises transporting an article or composition comprising said nanowire.

125. The method of any of claims 123 and 124, wherein said nanowire is substantially invisible to the human eye.

126. The method of claim 124, wherein said article or composition is selected from the group consisting of currency, a weapon, an explosive, a poison, a drug, a controlled substance, and a biological organism.

127. The method of claim 116, wherein said decoding comprises reading an electronic signature.

128. The method of claim 116, wherein said decoding comprises reading an optical signature.

129. The method of claim 116, wherein said decoding comprises reading a magnetic signature.

130. The method of claim 116, wherein said decoding comprises determining an emission spectrum of one or more domains comprising said nanowire heterostructure.

131. The method of claim 116, wherein said decoding comprises determining an absorption spectrum of one or more domains comprising said nanowire heterostructure.

132. The method of claim 116, wherein said nanowire is decoded after said nanowire is transported to a new location.

133. A method of tagging, tracking or identifying an article, a composition, or an animal, said method comprising:
contacting the article, composition or animal with one or more nanowire heterostructures of claim 1, whereby a nanowire heterostructure becomes associated with said article composition or animal.

134. The method of claim 133, further comprising:
detecting a nanowire heterostructure associated with said article, composition or animal.

135. The method of claim 133, wherein said animal is a non-human animal.

136. The method of claim 133, wherein said animal is a human.

137. The method of claim 136, wherein said human is associated with said nanowire heterostructure by contacting a composition or an article bearing one or more of said nanowire heterostructures.

138. The method of claim 133, wherein said article is an article selected from the group consisting of currency, and a weapon.

139. The method of claim 138, wherein said nanowire heterostructure is coded with information indicating a site of origin, of said article.

140. The method of claim 133, wherein said composition is a composition selected from the group consisting of an incendiary composition, an explosive composition, a toxic chemical composition, a bioweapon.

141. The method of claim 134, wherein said detecting comprises decoding said nanowire heterostructure to read the coded information.

142. The method of claim 141, wherein said decoding comprises reading an electronic signature.

143. The method of claim 141, wherein said decoding comprises reading an optical signature.

144. The method of claim 141, wherein said decoding comprises reading a magnetic signature.

145. The method of claim 141, wherein said decoding comprises determining an emission spectrum of one or more domains comprising said nanowire heterostructure.

146. The method of claim 141, wherein said decoding comprises determining an absorption spectrum of one or more domains comprising said nanowire heterostructure.

147. The method of claim 141, wherein said nanowire is decoded after said nanowire is transported to a new location.

148. The method of claim 133, wherein said nanowire heterostructure is not visible to the naked human eye.

149. A nanowire heterostructure attached to a linking agent.

150. The nanowire heterostructure of claim 149, further comprising an affinity reagent attached to said linking agent.

151. A method of detecting an analyte in a sample, said method comprising:
contacting said sample with a first binding moiety that binds to said analyte;
detecting a label associated with said analyte wherein said label comprises a nanowire heterostructure of claim 1, or a collection of nanowire heterostructures of claim 52, and said detecting indicates the presence and/or identity of said analyte in said sample.

152. The method of claim 151, wherein said first binding moiety is a moiety that specifically binds said analyte and said first binding moiety is attached to said label.

153. The method of claim 152, wherein said first binding moiety is attached to said label by a linker.

154. The method of claim 151, wherein said first binding moiety binds to and immobilizes said analyte and said analyte is contacted with a second binding moiety that specifically binds to said analyte where said second binding moiety is attached to said label.

155. The method of claim 151, wherein:
said first binding moiety binds to and immobilizes said analyte;
said analyte is contacted with a second binding moiety that specifically binds to said analyte; and
said second binding moiety is contacted with a third binding moiety that specifically binds said second binding moiety, wherein said third binding moiety is attached to said label.

156. The method of claim 154 or 155, wherein said first binding moiety non-specifically binds said analyte.

157. The method of claim 154 or 155, wherein said first binding moiety specifically binds said analyte.

158. The method of claim 151, wherein said first binding moiety is selected from the group consisting of a nucleic acid, an antibody, a polypeptide, a sugar, a lectin, and a carbohydrate.

159. The method of claim 154 or 155, wherein said second binding moiety is selected from the group consisting of a nucleic acid, an antibody, a polypeptide, a sugar, a lectin, and a carbohydrate.

160. The method of claim 155, wherein said third binding moiety is selected from the group consisting of a nucleic acid, an antibody, a polypeptide, a sugar, a lectin, and a carbohydrate.

161. The method of claim 151, wherein said sample is a biological sample.

162. The method of claim 151, wherein said sample is selected from the group consisting of a cell, a tissue, an organ, urine, blood, plasma, lymph, oral fluid, and cerebrospinal fluid.

163. The method of claim 151, wherein said detecting comprises decoding said nanowire heterostructure to read the identity of said analyte.

164. The method of claim 151, wherein said detecting comprises decoding the nanowire heterostructure to read the identity of the first binding moiety.

165. The method of claim 151, wherein said detecting comprises decoding the nanowire heterostructure to read the identity of the assay.

166. The method of claim 163, wherein said decoding comprises reading an electronic signature.

167. The method of claim 163, wherein said decoding comprises reading an optical signature.

168. The method of claim 163, wherein said decoding comprises reading a magnetic signature.

169. The method of claim 163, wherein said decoding comprises determining an emission spectrum of one or more domains comprising said nanowire heterostructure.

170. The method of claim 163, wherein said decoding comprises determining an absorption spectrum of one or more domains comprising said nanowire heterostructure.

171. A method of detecting an analyte in a sample containing or suspected of containing said analyte, said method comprising:
contacting said sample with a first binding moiety that specifically binds to said analyte, said binding moiety associated with a nanowire heterostructure of claim 1; and
detecting a label associated with said analyte wherein said detecting indicates the presence, quantity and/or identity of said analyte in said sample.

172. The method of claim 171, wherein encoded information in said nanowire heterostructure identifies said first binding moiety.

173. The method of claim 171, wherein encoded information in said nanowire heterostructure identifies said analyte.

174. A method of detecting a plurality of target analytes in a sample, said method comprising:
contacting said sample with a first plurality of binding moieties that specifically or non-specifically bind said target analytes; and
detecting a label associated with each species of target analyte, wherein said label comprises a nanowire heterostructure of claim 1, the nanowire heterostructure associated with each species of target analyte is distinguishable from the nanowire heterostructures associated with the other target analytes; and said detecting indicates the presence and/or identity of each of said target analytes present analyte in said sample.

175. The method of claim 174, wherein the first binding moieties comprise a plurality of different binding moieties each species of which specifically binds to one of said target analytes and each species of which is attached to a label comprising a nanowire heterostructure that uniquely identifies said species in said collection of species.

176. The method of claim 174, wherein the nanowire heterostructure uniquely identifies the binding moiety associated therewith

177. The method of claim 175, wherein the labels are attached to the first binding moieties by linkers.

178. The method of claim 174, wherein the first binding moieties bind to and immobilize the target analytes and the target analytes are contacted with second binding moieties comprising a plurality of binding moiety species where said plurality comprises a collection of species of binding moiety that each specifically bind to one of said target analytes, each species being attached to a to a label comprising a nanowire heterostructure that uniquely identifies said species in said collection of species.

179. The method of claim 174, wherein:
the first binding moieties bind to and immobilize the target analytes;
the target analytes are contacted with second binding moieties second binding moieties comprising a plurality of binding moiety species where said plurality comprises a collection of species of binding moiety that each specifically bind to one of said target analytes; and
the second binding moieties are contacted with third binding moieties comprising a plurality of binding moiety species where said plurality comprises a collection of species of binding moiety that each specifically bind to one of the species of second binding moieties, each species of third binding moiety being attached to a to a label comprising a nanowire heterostructure that uniquely identifies said species in said collection of species third binding moieties.

180. The method of claim 178 or 179, wherein the first binding moieties non-specifically bind said target analytes.

181. The method of claim 178 or 179, wherein the first binding moieties specifically bind said target analytes.

182. The method of claim 174, wherein the first binding moieties are selected from the group consisting of a nucleic acid, an antibody, a polypeptide, a sugar, a lectin, and a carbohydrate.

183. The method of claim 178 or 179, wherein the second binding moieties are selected from the group consisting of a nucleic acid, an antibody, a polypeptide, a sugar, a lectin, and a carbohydrate.

184. The method of claim 179, wherein the third binding moieties are selected from the group consisting of a nucleic acid, an antibody, a polypeptide, a sugar, a lectin, and a carbohydrate.

185. The method of claim 174, wherein said sample is selected from the group consisting of a cell, a tissue, an organ, urine, blood, plasma, lymph, oral fluid, and cerebrospinal fluid.

186. The method of claim 174, wherein said detecting comprises decoding the nanowire heterostructures to read the identity of the analytes.

187. The method of claim 174, wherein said detecting comprises decoding the nanowire heterostructure to read the identity of the first binding moiety.

188. The method of claim 174, wherein said detecting comprises decoding the nanowire heterostructure to read the identity of the assay.

189. The method of claim 186, wherein said decoding comprises reading an electronic signature.

190. The method of claim 186, wherein said decoding comprises reading an optical signature.

191. The method of claim 186, wherein said decoding comprises reading a magnetic signature.

192. The method of claim 186, wherein said decoding comprises determining an emission spectrum of one or more domains comprising the nanowire heterostructures.

193. The method of claim 186, wherein said decoding comprises determining an absorption spectrum of one or more domains comprising the nanowire heterostructures.

194. A method of detecting a plurality of target analytes, each present or suspected of being present in a sample, said method comprising:
contacting said sample with a first plurality of binding moieties that specifically bind said target analytes, said binding moieties each associated with a nanowire heterostructure of claim 1;
the nanowire heterostructure associated with each type of binding moiety specific for a different analyte being distinguishable from the nanowire heterostructures associated with binding moieties specific for every other of the target analytes;
detecting a label associated with each species of target analyte, wherein said detecting indicates the presence, quantity and/or identity of each of said target analytes present in said sample.

195. The method of claim 194, wherein encoded information in said nanowire heterostructures identifies said first binding moieties to which they are bound.

196. The method of claim 194, wherein encoded information in said nanowire heterostructure identifies said analyte to which said binding moieties bound to said nanowire heterostructures bind specifically.

197. A method of detecting the presence or quantity of a first target analyte, in a sample, said method comprising:
providing a first detection element comprising a first nanowire heterostructure of claim 1 associated with a first specific binding moiety;
contacting said binding moiety with said sample whereby said binding moiety specifically binds said first target analyte if said first target analyte is present in said sample;
detecting binding of said first target analyte to said first detection element; and
reading the information encoded in said nanowire heterostructure to determine the identity of said first target analyte.

198. The method of claim 197, wherein said method further comprises”
providing at least a second detection element comprising a second nanowire heterostructure of claim 1 associated with a second specific binding moiety where said second biding moiety specifically binds a second target analyte different from said first target analyte;
contacting said binding moiety with said sample whereby said second binding moiety specifically binds said second target analyte if said second target analyte is present;
detecting binding of said second target analyte to said second detection element; and
reading the information encoded in said second nanowire heterostructure to determine the identity of said second target analyte.

199. The method of claim 198, wherein said first and second target analytes are the same target analyte.

200. The method of claim 198, wherein said method uses at least 10 different detection elements.

201. The method of claim 197 or 198, wherein the third binding moieties are selected from the group consisting of a nucleic acid, an antibody, a polypeptide, a sugar, a lectin, and a carbohydrate.

202. The method of claim 197 or 198, wherein said sample is selected from the group consisting of a cell, a tissue, an organ, urine, blood, plasma, lymph, oral fluid, and cerebrospinal fluid.

203. The method of claim 197 or 198, wherein said reading comprises reading an electronic signature.

204. The method of claim 197 or 198, wherein said reading comprises reading an optical signature.

205. The method of claim 197 or 198, wherein said reading comprises reading a magnetic signature.

206. The method of claim 197 or 198, wherein said reading comprises determining an emission spectrum of one or more domains comprising the nanowire heterostructures.

207. The method of claim 197 or 198, wherein said reading comprises determining an absorption spectrum of one or more domains comprising the nanowire heterostructures.

208. The method of claim 197, wherein detecting the binding of the first target analyte to the first detection element comprises detecting a label of attached to a detector moiety that specifically binds said first target analyte.

209. A method of assembling a device, said method comprising:
providing a collection of nanowire heterostructures according to claim 69;
assembling said nanowire heterostructures into a device; and
reading the information encoded in said nanowire heterostructures to determine which nanowire heterostructure is located at which location in said device.

210. The method of claim 209, further comprising placing the identity and location of each active nanowire heterostructure in a lookup table.

211. The method of claim 210, wherein said lookup table is an element of said device.

212. The method of claim 210, wherein said lookup table is a component of a reader for said device.

213. The method of claim 209, wherein said a collection of nanowire heterostructures comprises a plurality of species wherein each species being differently functionalized than the other species comprising said plurality and further wherein the functionalized species are uniquely identified by the information coded into the nanowire heterostructures.

214. The method of claim 213, wherein the nanowire heterostructures are functionalized with binding moieties independently selected from the group consisting of a nucleic acid, an antibody, a polypeptide, a sugar, a lectin, and a carbohydrate.

215. The method of claim 213, wherein the nanowire heterostructures are functionalized with functional groups independently selected from the group consisting of a hydroxyl, an amino, a carboxyl, a thiol, and a halide.

216. The method of claim 209, wherein said device is selected from the group consisting of a logic circuit, a sensor, a biodetection system, a nano-CHEM-FET array, an electrically addressable device, an optically addressable device, and an array.

217. A method of detecting a label among a plurality of intermingled labels, said method comprising:
providing a plurality of intermingled labels comprising nanowire heterostructures of claim 1, wherein different species of nanowire heterostructure encode a different signature;
decoding the signature of one of said nanowire heterostructures to identify said nanowire heterostructure whereby the label of said nanowire heterostructure is detected and distinguished from other labels comprising said plurality.

218. A method of detecting the contacting, handling, or association of a first animal or a first composition or article of manufacture by a second animal or a second composition or article of manufacture, said method comprising:
providing said first animal or composition or article of manufacture labeled with one or more of the nanowire heterostructures of claim 1; and
scanning a said second animal composition or article of manufacture suspected of contacting said first animal or composition or article of manufacture to detect said nanowire heterostructure, where the presence of said nanowire heterostructure on said second animal, composition, or article of manufacture, indicates that said second animal, composition or article of manufacture has contacted said first animal, composition, or article of manufacture.

219. The method of claim 218, wherein said first animal is a human.

220. The method of claim 218, wherein said second animal is a human.

221. The method of claim 218, wherein said composition is selected from the group consisting of a toxic chemical, an explosive, a drug, and a bacterium.

222. The method of claim 218, wherein said article of manufacture is selected from the group consisting of an insured item of value, a controlled substance, currency, and a weapon.

223. An inventory label generating method comprising:
generating a plurality of candidate labels wherein said labels comprise nanowire heterostructures according to claim 1;
selecting a plurality of acceptable distinguishable labels from among the candidate labels by reading the information encoded in said candidate labels and selecting labels having different and distinguishable codes.
